(19) United States
(12) Patent Application Publication
(10) Pub. No.: US 2025/0241146 A1
(43) Pub. Date: Jul. 24, 2025

(54) DISPLAY DEVICE

(71) Applicant: Samsung Display Co., LTD., Yongin-si (KR)

(72) Inventors: Dong Hee SHIN, Yongin-si (KR); Sun Kwun SON, Yongin-si (KR); Na Hyeon CHA, Yongin-si (KR)

(21) Appl. No.: 18/918,782

(22) Filed: Oct. 17, 2024

(30) Foreign Application Priority Data
Jan. 23, 2024 (KR) 10-2024-0010415

(51) Int. Cl. H10K 59/131; H10K 59/121; H10K 59/65

(52) U.S. Cl. CPC H10K 59/131; H10K 59/1213; H10K 59/65

(57) ABSTRACT

A display device includes a substrate including a display area in which emission areas are arranged and a non-display area around the display area; a circuit layer on the substrate; and an element layer on the circuit layer, and including light emitting elements respectively located in the emission areas, wherein the circuit layer includes: light emitting pixel drivers electrically connected to the light emitting elements, and arranged side by side with each other along a first direction and a second direction; data lines extending in the second direction, and transmitting a data signal to the light emitting pixel drivers; first auxiliary lines extending in the first direction; second auxiliary lines extending in the second direction and adjacent to the data lines in the first direction; third auxiliary lines extending in the second direction, and located between the second auxiliary lines in the first direction; and first connection auxiliary electrodes.

### CROSS-REFERENCE TO RELATED APPLICATION

The present application claims priority to and the benefit of Korean Patent Application No. 10-2024-0010415 filed on Jan. 23, 2024, in the Korean Intellectual Property Office, the entire disclosure of which is incorporated herein by reference.

### BACKGROUND

### 1. Field

The present disclosure relates to a display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer made of an organic light emitting material. As described above, the organic light emitting display device implements image display using a self-light emitting element, and thus may have relatively superior performance in power consumption, response speed, luminous efficiency, luminance, and wide viewing angle compared to other display devices.

One surface of the display device may be a display surface including a display area in which an image is displayed and a non-display area that is a periphery of the display area. Emission areas emitting light with respective luminances and colors may be arranged in the display area.

### SUMMARY

The display device may include light emitting elements respectively disposed in emission areas, and light emitting pixel drivers respectively electrically connected to the light emitting elements.

The light emitting pixel drivers may supply a driving current corresponding to a data signal of the emission areas to the light emitting elements.

However, in order to supply the driving current more uniformly and stably, the light emitting pixel drivers may include not only a driving transistor that generates the driving current, but also transistors for initializing the potential of nodes connected to the driving transistor and/or the light emitting element and constant voltage lines connected thereto. As a result, the width of each of the light emitting pixel drivers increases, so there is a problem that there is a limit to the improvement in resolution.

In addition, due to wiring resistance, it may be difficult for constant voltages for driving current generation and initialization to be uniformly transmitted throughout the display area, and in this case, there is a problem of image quality degradation caused by luminance differences between areas.

In view of the above, aspects and features of embodiments of the present disclosure provide a display device in which the width of each of light emitting pixel drivers may be reduced, while constant voltages may be transmitted to the light emitting pixel drivers through mesh-shaped wires with relatively low resistance, thereby being desirable for achieving high resolution.

However, aspects and features of embodiments of the present disclosure are not restricted to the one set forth herein. The above and other aspects and features of embodiments of the present disclosure will become more apparent to one of ordinary skill in the art to which the present disclosure pertains by referencing the detailed description of the present disclosure given below.

According to one or more embodiments of the present disclosure, there is provided a display device including a display device including: a substrate including a display area in which emission areas are arranged and a non-display area around the display area; a circuit layer on the substrate; and an element layer on the circuit layer, and including light emitting elements respectively located in the emission areas, wherein the circuit layer includes: light emitting pixel drivers electrically connected to the light emitting elements, and arranged side by side with each other along a first direction and a second direction; data lines extending in the second direction, and transmitting a data signal to the light emitting pixel drivers; first auxiliary lines extending in the first direction; second auxiliary lines extending in the second direction and adjacent to the data lines in the first direction; third auxiliary lines extending in the second direction, and located between the second auxiliary lines in the first direction; and first connection auxiliary electrodes respectively located in the light emitting pixel drivers, having an island shape, and spaced from the first auxiliary lines.

The circuit layer further includes second connection auxiliary electrodes having an island shape and respectively overlapping the first connection auxiliary electrodes, and respectively electrically connected to the first connection auxiliary electrodes through first auxiliary connection holes, and wherein the second connection auxiliary electrodes are electrically connected to the second auxiliary lines through second auxiliary connection holes.

The circuit layer further includes: a first initialization voltage line electrically connected to an initialization voltage extension line transmitting a first initialization voltage and extending in the first direction, having an island shape, and spaced from the first connection auxiliary electrodes; a second initialization voltage line extending in the first direction, spaced from the first connection auxiliary electrodes, and transmitting a second initialization voltage; and third connection auxiliary electrodes overlapping the third auxiliary lines and having an island shape, and spaced from the second connection auxiliary electrodes, wherein the third connection auxiliary electrodes are electrically connected to the third auxiliary lines through third auxiliary connection holes.

The light emitting pixel drivers includes a first light emitting pixel driver and a second light emitting pixel driver that are adjacent to each other in the first direction, wherein one of the first auxiliary lines overlaps the first light emitting pixel driver and the second light emitting pixel driver, wherein the second auxiliary lines include a second auxiliary line overlapping the first light emitting pixel driver, and another second auxiliary line overlapping the second light emitting pixel driver, wherein the third auxiliary lines include a third auxiliary line adjacent to a boundary between the first light emitting pixel driver and the second light emitting pixel driver, and the first initialization voltage line is located between the first connection auxiliary electrode of the first light emitting pixel driver and the first connection auxiliary electrode of the second light emitting pixel driver in the first direction, and overlaps the third auxiliary line.

Each of the first connection auxiliary electrode of the first light emitting pixel driver and the first connection auxiliary electrode of the second light emitting pixel driver is electrically connected to one of the first auxiliary lines, the first initialization voltage line, or the second initialization voltage line through a first connection auxiliary line.

The third connection auxiliary electrodes include a third connection auxiliary electrode electrically connected to the third auxiliary line, and one of the second connection auxiliary electrode of the first light emitting pixel driver or the second connection auxiliary electrode of the second light emitting pixel driver is electrically connected, through a second connection auxiliary line, to a third connection auxiliary electrode between the second connection auxiliary electrode of the first light emitting pixel driver and the second connection auxiliary electrode of the second light emitting pixel driver from among the third connection auxiliary electrodes.

A bypass area on one side of the display area includes: a bypass middle area; a first bypass side area parallel to the bypass middle area in the first direction and in contact with the non-display area in the first direction; and a second bypass side area located between the bypass middle area and the first bypass side area, the data lines including a first data line in the first bypass side area, and a second data line in the second bypass side area, the first auxiliary lines including: a first bypass auxiliary line electrically connected to the first data line; and power auxiliary horizontal lines configured to transmit, between a first power and a second power for driving the light emitting elements, the second power, the second auxiliary lines including a second bypass auxiliary line adjacent to the second data line and electrically connected to the first bypass auxiliary line, and auxiliary vertical lines, the auxiliary vertical lines being a remainder of the second auxiliary lines excluding the second bypass auxiliary line and including: a first auxiliary vertical line configured to transmit the second power; a second auxiliary vertical line configured to transmit the first initialization voltage; and a third auxiliary vertical line configured to transmit the second initialization voltage.

The first bypass auxiliary line from among the first auxiliary lines is electrically connected to the first connection auxiliary electrode of one of the light emitting pixel drivers through a first connection auxiliary line, and the second connection auxiliary electrode of the one light emitting pixel driver is electrically connected to the second bypass auxiliary line from among the second auxiliary lines through a second auxiliary connection hole.

From among the first auxiliary lines, the power auxiliary horizontal line is electrically connected to the first connection auxiliary electrode of one of the light emitting pixel drivers through a first connection auxiliary line, and wherein the second connection auxiliary electrode of the one light emitting pixel driver is electrically connected to the first auxiliary vertical line from among the second auxiliary lines through a second auxiliary connection hole.

The first initialization voltage line is electrically connected to the first connection auxiliary electrode of one of the light emitting pixel drivers through a first connection auxiliary line, and wherein the second connection auxiliary electrode of the one light emitting pixel driver is electrically connected to the second auxiliary vertical line from among the second auxiliary lines through a second auxiliary connection hole.

The second initialization voltage line is electrically connected to the first connection auxiliary electrode of one of the light emitting pixel drivers through a first connection auxiliary line, and the second connection auxiliary electrode of the one light emitting pixel driver is electrically connected to the third auxiliary vertical line from among the second auxiliary lines through a second auxiliary connection hole.

The circuit layer further includes third connection auxiliary electrodes overlapping the third auxiliary lines and spaced from the second connection auxiliary electrodes, and the third auxiliary lines include: a power additional line configured to transmit the second power; a first initialization voltage additional line configured to transmit the first initialization voltage; and a second initialization voltage additional line configured to transmit the second initialization voltage.

From among the first auxiliary lines, the power auxiliary horizontal line is electrically connected to the first connection auxiliary electrode of one of the light emitting pixel drivers through a first connection auxiliary line, wherein the second connection auxiliary electrode of the light emitting pixel driver is electrically connected to one of the third connection auxiliary electrodes overlapping the power additional line from among the third connection auxiliary electrodes through a second connection auxiliary line, and wherein the one third connection auxiliary electrode is electrically connected to the power additional line through a third auxiliary connection hole.

The first initialization voltage line is electrically connected to the first connection auxiliary electrode of one of the light emitting pixel drivers through a first connection auxiliary line, wherein the second connection auxiliary electrode of the light emitting pixel driver is electrically connected to one of the third connection auxiliary electrodes overlapping the first initialization voltage additional line from among the third connection auxiliary electrodes through a second connection auxiliary line, and wherein the third connection auxiliary electrode is electrically connected to the first initialization voltage additional line through a third auxiliary connection hole.

The second initialization voltage line is electrically connected to the first connection auxiliary electrode of one of the light emitting pixel drivers through a first connection auxiliary line, wherein the second connection auxiliary electrode of the one light emitting pixel driver is electrically connected to one of the third connection auxiliary electrodes overlapping the second initialization voltage additional line from among the third connection auxiliary electrodes through a second connection auxiliary line, and wherein the one third connection auxiliary electrode is electrically connected to the second initialization voltage additional line through a third auxiliary connection hole.

The display area includes a non-emission area which is a separation region between the emission areas; and light sensing areas in parts of the non-emission area, wherein the element layer further includes light sensing elements respectively located in the light sensing areas, wherein the circuit layer further includes: light sensing pixel drivers electrically connected to the light sensing elements; a reset control line extending in the first direction, and configured to transmit a reset control signal for resetting the light sensing pixel drivers; and a reset voltage line configured to transmit a reset voltage to the light sensing pixel drivers, wherein the auxiliary vertical lines of the second auxiliary lines further include at least one of a fourth auxiliary vertical line configured to transmit the reset voltage, or a fifth auxiliary vertical line configured to transmit the reset control signal.

The reset voltage line is electrically connected to the second connection auxiliary electrode of one of the light emitting pixel drivers through a third connection auxiliary line, and wherein the second connection auxiliary electrode of the one of the light emitting pixel drivers is electrically connected to the fourth auxiliary vertical line from among the second auxiliary lines through a second auxiliary connection hole.

The reset control line is electrically connected to the first connection auxiliary electrode of one of the light emitting pixel drivers through a reset control connection hole and a first connection auxiliary line, and wherein the second connection auxiliary electrode of the one light emitting pixel driver is electrically connected to the fifth auxiliary vertical line from among the second auxiliary lines through a second auxiliary connection hole.

The circuit layer further includes: a first semiconductor layer on the substrate; a first gate insulating layer covering the first semiconductor layer; a first gate conductive layer on the first gate insulating layer; a second gate insulating layer covering the first gate conductive layer; a second gate conductive layer on the second gate insulating layer; an additional interlayer insulating layer covering the second gate conductive layer; a second semiconductor layer on the additional interlayer insulating layer; a third gate insulating layer covering the second semiconductor layer; a third gate conductive layer on the third gate insulating layer; an interlayer insulating layer covering the third gate conductive layer; a first source-drain conductive layer on the interlayer insulating layer; a first planarization layer covering the first source-drain conductive layer; a second source-drain conductive layer on the first planarization layer; a second planarization layer covering the second source-drain conductive layer; a third source-drain conductive layer on the second planarization layer; and a third planarization layer covering the third source-drain conductive layer, wherein the first auxiliary lines, the first connection auxiliary electrodes, the first initialization voltage line, and the second initialization voltage line are on the first source-drain conductive layer, wherein the second connection auxiliary electrodes and the third connection auxiliary electrodes are in the second source-drain conductive layer, and wherein the second auxiliary lines and the third auxiliary lines are in the third source-drain conductive layer.

In one or more embodiments, a display device includes: a substrate including a display area in which emission areas are arranged and a non-display area around the display area; a circuit layer on the substrate; and an element layer on the circuit layer, and including light emitting elements respectively located in the emission areas, wherein the circuit layer includes: light emitting pixel drivers electrically connected to the light emitting elements, and arranged side by side with each other in a first direction and a second direction; data lines extending in the second direction, and configured to transmit a data signal to the light emitting pixel drivers; first auxiliary lines extending in the first direction; second auxiliary lines extending in the second direction and adjacent to the data lines in the first direction; third auxiliary lines extending in the second direction, and located between the second auxiliary lines in the first direction; first connection auxiliary electrodes respectively located in the light emitting pixel drivers, having an island shape, and spaced from the first auxiliary lines; second connection auxiliary electrodes, having an island shape, and respectively overlapping the first connection auxiliary electrodes, respectively electrically connected to the first connection auxiliary electrodes through first auxiliary connection holes, and electrically connected to the second auxiliary lines through second auxiliary connection holes; third connection auxiliary electrodes overlapping the third auxiliary lines, having an island shape, and spaced from the second connection auxiliary electrodes, and electrically connected to the third auxiliary lines through third auxiliary connection holes; a first initialization voltage line electrically connected to an initialization voltage extension line configured to transmit a first initialization voltage and extending in the first direction, having an island shape, and spaced from the first connection auxiliary electrodes; and a second initialization voltage line extending in the first direction, spaced from the first connection auxiliary electrodes, and configured to transmit a second initialization voltage, wherein the first auxiliary lines include: a first bypass auxiliary line electrically connected to a first data line adjacent to the non-display area in the first direction from among the data lines; and power auxiliary horizontal lines configured to transmit, between a first power and a second power for driving the light emitting elements, the second power, and wherein the second auxiliary lines include: a second bypass auxiliary line electrically connected to the first bypass auxiliary line and adjacent to a second data line spaced from the non-display area than the first data line in the first direction from among the data lines; and auxiliary vertical lines, the auxiliary vertical lines being a remainder excluding the second bypass auxiliary line, wherein the second bypass auxiliary line is electrically connected to the first bypass auxiliary line through a first connection auxiliary electrode, a first connection auxiliary line, and a second connection auxiliary electrode in a bypass connection light emitting pixel driver overlapping a crossing of the first bypass auxiliary line and the second bypass auxiliary line from among the light emitting pixel drivers, and wherein the auxiliary vertical lines include: a first auxiliary vertical line electrically connected to the power auxiliary horizontal lines through a first connection auxiliary electrode, a first connection auxiliary line, and a second connection auxiliary electrode located in a power connection light emitting pixel driver from among the light emitting pixel drivers; a second auxiliary vertical line, configured to transmit the first initialization voltage, electrically connected to the first initialization voltage line through a first connection auxiliary electrode, a first connection auxiliary line, and a second connection auxiliary electrode in a first initialization connection light emitting pixel driver from among the light emitting pixel drivers; and a third auxiliary vertical line electrically connected to the second initialization voltage line through a first connection auxiliary electrode, a first connection auxiliary line, and a second connection auxiliary electrode in a second initialization connection light emitting pixel driver from among the light emitting pixel drivers.

Accordingly, in one of the first light emitting pixel driver and the second light emitting pixel driver, one wire, from among one first auxiliary line, the first initialization voltage line, and the second initialization voltage line, connected to the first connection auxiliary electrode may be electrically connected to the third auxiliary line through the first connection auxiliary electrode, the second connection auxiliary electrode, and the third connection auxiliary electrode.

As described above, according to one or more embodiments, the first connection auxiliary electrode spaced from the first auxiliary lines, the second connection auxiliary electrode overlapping the first connection auxiliary electrode, and a portion of the third connection auxiliary electrode spaced from the second connection auxiliary electrode may be disposed in each of the light emitting pixel drivers. In addition, by selectively disposing the first connection auxiliary line that connects one of the first initialization voltage line and the second initialization voltage line to the first connection auxiliary electrode, and the second connection auxiliary line that connects the second connection auxiliary electrode to the third connection auxiliary electrode, mesh-shaped wires including electrical connection between wires in the first direction and wires in the second direction may be provided.

In other words, even if protrusions having holes for the electrical connection between the wires in the first direction and the wires in the second direction are not provided for each of the wires, mesh-shaped wires may be provided, so that the width of each of the light emitting pixel drivers may be reduced, which may be advantageous for achieving high resolution.

However, effects, aspects, and features according to one or more embodiments of the present disclosure are not limited to those exemplified above and various other effects, aspects, and features are incorporated herein.

### BRIEF DESCRIPTION OF THE DRAWINGS

The above and other aspects and features of embodiments of the present disclosure will become more apparent by describing in detail embodiments thereof with reference to the attached drawings, in which:

FIG. 1 is a perspective view showing an electronic device according to one or more embodiments;

FIG. 2 is an exploded perspective view of the electronic device shown in FIG. 1;

FIG. 3 is a plan view illustrating the display device of FIG. 2;

FIG. 4 is a cross-sectional view taken along the line A-A′ of FIG. 3;

FIG. 5 is a layout diagram illustrating a part B of FIG. 3;

FIG. 6 is an diagram illustrating a scanning function by the light sensing areas shown in FIG. 5;

FIG. 7 is a block diagram showing a circuit layer of FIG. 4;

FIG. 8 is an equivalent circuit diagram of the light emitting pixel driver and the light sensing pixel driver shown in FIG. 7;

FIG. 9 is a cross-sectional view illustrating a first transistor, a second transistor, a fourth transistor, a sixth transistor, and one light emitting element of FIG. 8;

FIG. 10 is a plan view illustrating the substrate of FIG. 4 according to one or more embodiments;

FIG. 11 is a layout diagram illustrating a part C of FIG. 10;

FIG. 12 is a cross-sectional view taken along the line E-E′ of FIG. 11;

FIG. 13 is a plan view showing a part D of FIG. 10 according to one embodiment;

FIGS. 14, 15, 16, 17, and 18 are plan views illustrating a part of each of the first light emitting pixel driver and the second light emitting pixel driver of FIG. 13 according to one or more embodiments;

FIG. 19 is a plan view showing a part D of FIG. 10 according to one or more embodiments; and

FIGS. 20 and 21 are plan views showing a part of each of a first light emitting pixel driver and a second light emitting pixel driver of FIG. 19 according to one or more embodiments.

### DETAILED DESCRIPTION

Embodiments of the present disclosure will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts that are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” and/or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” and “at least one of A or B” may each be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments will be described with reference to the accompanying drawings.

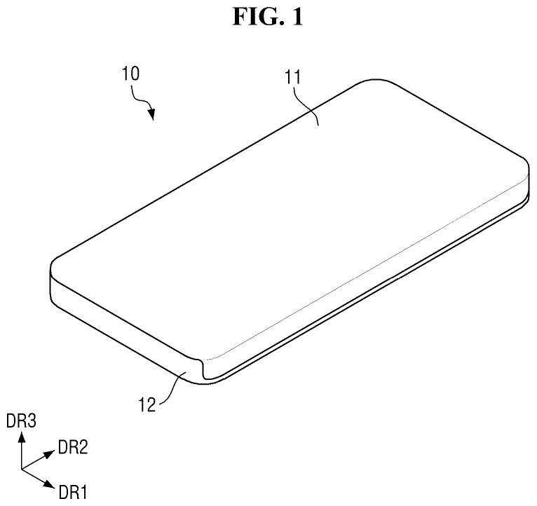

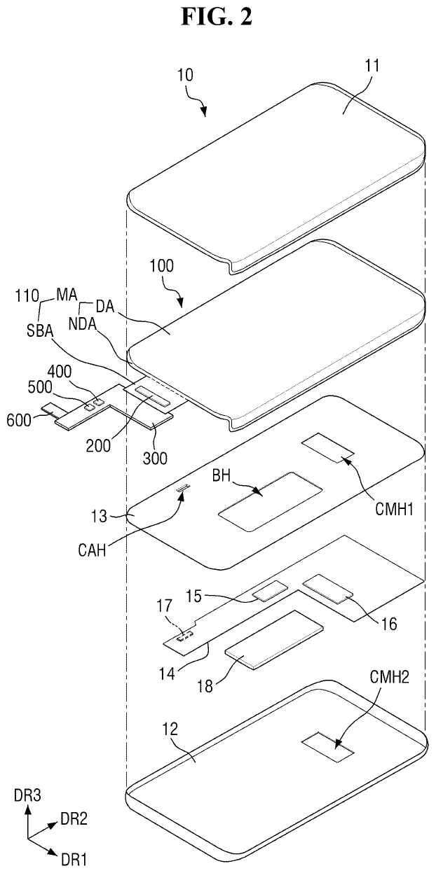

FIG. 1 is a perspective view showing an electronic device according to one or more embodiments. FIG. 2 is an exploded perspective view of the electronic device shown in FIG. 1.

Referring to FIG. 1, an electronic device 10 according to one or more embodiments is a device having a function of displaying an image in a display area. The electronic device 10 may provide portability. For example, the electronic device 10 may be a portable electronic device such as a mobile phone, a smartphone, a tablet personal computer (PC), a smart watch, a watch phone, a mobile communication terminal, an electronic notebook, an electronic book, a portable multimedia player (PMP), a navigation device, and/or an ultra-mobile PC (UMPC).

However, the electronic device 10 according to one or more embodiments is not limited to a portable electronic device, and may be a large-sized device such as a television, a laptop computer, a monitor, a billboard, and/or an Internet-of-Things (IoT) device.

The electronic device 10 according to one or more embodiments may include a cover window 11 and a lower cover 12, which are provided as a housing to protect a display device 100 (see FIG. 2).

Referring to FIG. 2, the electronic device 10 may further include the display device 100, a bracket 13, and a main circuit board 14, which are accommodated between the cover window 11 and the lower cover 12.

The display device 100 may include a main region MA including a display area DA where an image is displayed and a non-display area NDA around the display area DA along an edge or a periphery of the display area DA, and a sub-region SBA protruding from one side of the main region MA.

The display device 100 may further include a display driving circuit 200 disposed in the sub-region SBA, a display circuit board 300 bonded to one side of the sub-region SBA, a touch driving circuit 400 and a scanning driving circuit 500 mounted on the display circuit board 300, and a cable 600 extending from one side of the display circuit board 300.

In the present disclosure, a first direction DR1 may be a direction parallel to a short side of the electronic device 10 in a plan view, that is, a horizontal direction of the electronic device 10. A second direction DR2 may be a direction parallel to a long side of the electronic device 10 in a plan view, that is, a vertical direction of the electronic device 10. A third direction DR3 may be a thickness direction of the electronic device 10.

The electronic device 10 may have a shape close to a rectangular shape in a plan view. For example, the electronic device 10 may have a rectangular shape, in a plan view, having a short side extending in the first direction DR1 and a long side extending in the second direction DR2. A corner where the short side extending in the first direction DR1 and the long side extending in the second direction DR2 meet may be right-angled or rounded with a suitable curvature (e.g., a predetermined curvature). The planar shape of the electronic device 10 is not limited to the rectangular shape, and may be formed in another polygonal shape, a circular shape, and/or an elliptical shape.

The cover window 11 may be disposed on the display device 100 to cover the top surface of the display device 100. The cover window 11 may serve to protect the top surface of the display device 100.

The cover window 11 may include a light transmitting portion that is transparent and a light blocking portion that is opaque.

The light transmitting portion may overlap the display area DA of the display device 100 in the third direction DR3, and the light blocking portion may overlap the non-display area NDA of the display device 100 in the third direction DR3.

The cover window 11 may include a top surface portion forming the top surface of the electronic device 10, a left surface portion forming the left side surface of the electronic device 10, and a right surface portion forming the right side surface of the electronic device 10. The left surface portion of the cover window 11 may extend from the left side of the top surface portion, and the right surface portion thereof may extend from the right side of the top surface portion.

Each of the top, left, and right surface portions of the cover window 11 may include the light transmitting portion and the light blocking portion.

The light transmitting portion of the cover window 11 may be disposed on most of each of the top, left, and right surface portions of the cover window 11.

The light blocking portion of the cover window 11 may be disposed at the upper edge and lower edge of the top surface portion of the cover window 11, the upper edge, left edge, and lower edge of the left surface portion of the cover window 11, and the upper edge, right edge, and lower edge of the right surface portion of the cover window 11.

The display device 100 may be disposed below the cover window 11.

That is, the cover window 11 may be disposed on the display device 100.

The display device 100 may include the main region MA serving as a display surface and the sub-region SBA protruding from one side of the main region MA.

The main region MA may include the display area DA displaying an image and the non-display area NDA that is a peripheral area of the display area DA.

The display area DA may be disposed in most of the main region MA. The display area DA may be disposed at the center of the main region MA.

The non-display area NDA may be disposed outside the display area DA.

The non-display area NDA may be an edge area of the main region MA.

The sub-region SBA may protrude from one side of the main region MA in the second direction DR2.

The length of the sub-region SBA in the first direction DR1 may be less than or equal to the length of the main region MA in the first direction DR1. The length of the sub-region SBA in the second direction DR2 may be less than the length of the main region MA in the second direction DR2, but is not limited thereto.

Because a part of the sub-region SBA is transformed to be bent, another part of the sub-region SBA may overlap the main region MA in the third direction DR3.

The display driving circuit 200 may be arranged in the sub-region SBA.

The display device 100 may include a top surface portion facing the top surface portion of the cover window 11, a left surface portion facing the left surface portion of the cover window 11, and a right surface portion facing the right surface portion of the cover window 11. The left surface portion of the display device 100 may extend from the left side of the top surface portion, and the right surface portion of the display device 100 may extend from the right side of the top surface portion.

Each of the top, left, and right surface portions of the display device 100 may include the display area DA and the non-display area NDA.

The display area DA may be disposed on most of each of the top, left, and right surface portions of the display device 100.

The non-display area NDA may be disposed at the upper edge and lower edge of the top surface portion of the display device 100, the upper edge, left edge, and lower edge of the left surface portion of the display device 100, and the upper edge, right edge, and lower edge of the right surface portion of the display device 100.

The display driving circuit 200 may be mounted on the sub-region SBA of the display device 100, and the display circuit board 300 may be attached thereto.

One end of the display circuit board 300 may be attached onto pads disposed on the lower edge of the sub-region SBA of the display device 100 by using an anisotropic conductive film.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

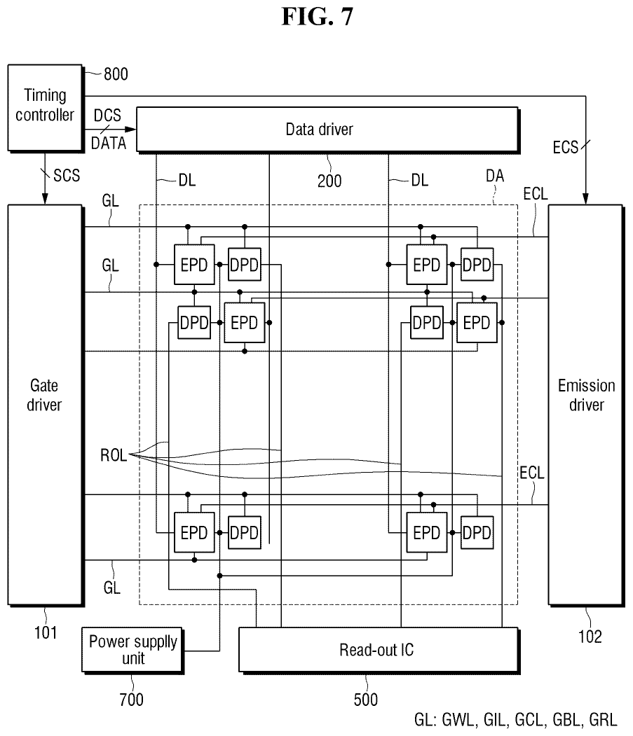

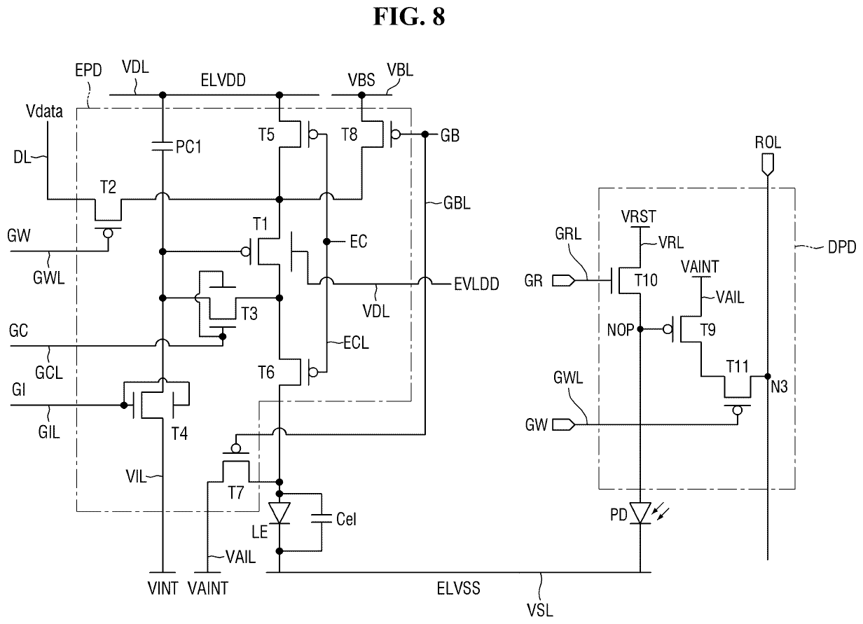

Based on control signals and power voltages supplied from the display circuit board 300, the display driving circuit 200 may transmit a data signal Vdata (see FIG. 8) of light emitting pixel drivers EPD (see FIG. 7) of the display area DA to data lines DL (see FIG. 7).

The display driving circuit 200 may be provided as an integrated circuit (IC) and mounted on the sub-region SBA of the display device 100 by a chip on glass (COG) method, a chip on plastic (COP) method, and/or an ultrasonic method. However, this is only an example, and the present disclosure is not limited thereto. For example, the display driving circuit 200 may be mounted on the display circuit board 300.

According to one or more embodiments, the touch driving circuit 400 and the scanning driving circuit 500 may be further mounted in the sub-region SBA of the display device 100.

Alternatively, as shown in FIG. 2, the touch driving circuit 400 and the scanning driving circuit 500 may be mounted on the display circuit board 300.

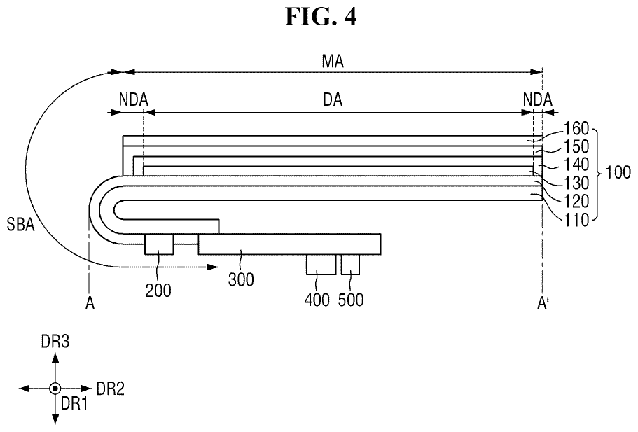

The touch driving circuit 400 may be electrically connected to a touch sensor layer 150 (see FIG. 4) of the display device 100.

The scanning driving circuit 500 may be electrically connected to light sensing elements PD (see FIG. 8) through light sensing pixel drivers DPD (see FIG. 7) and read-out lines ROL (see FIG. 7) of the display area DA.

The bracket 13 may be disposed under the display device 100.

The bracket 13 may include plastic, metal, or both plastic and metal. The bracket 13 may include a first camera hole CMH1 into which a camera 16 is inserted, a battery hole BH into which a battery 18 is disposed, and a cable hole CAH through which the cable 600 connected to the display circuit board 300 passes.

The main circuit board 14 and the battery 18 may be disposed under the bracket 13. The main circuit board 14 may be a printed circuit board (PCB) or a flexible printed circuit board (FPCB).

The main circuit board 14 may include a main processor 15, the camera 16, and a main connector 17. The main processor 15 may be formed as an integrated circuit.

The camera 16 may be disposed on both the top surface and the bottom surface of the main circuit board 14, the main processor 15 may be disposed on the top surface of the main circuit board 14, and the main connector 17 may be disposed on the bottom surface of the main circuit board 14.

The main processor 15 may control all functions of the electronic device 10.

For example, the main processor 15 may output digital video data to the display driving circuit 200 through the display circuit board 300 such that the display device 100 displays an image. In addition, the main processor 15 may receive touch data including user's touch coordinates from the touch driving circuit 400, determine whether or not the user has touched and/or approached, and then perform an operation corresponding to the user's touch input and/or approach input. For example, the main processor 15 may perform an operation or execute an application indicated by an icon touched by the user.

In addition, the main processor 15 may receive scanning data from the scanning driving circuit 500, and perform an operation or execute an application based on whether or not the scanning data is valid.

The main processor 15 may be an application processor formed of an integrated circuit, a central processing unit (CPU), and/or a system chip.

The camera 16 may process an image frame of a still image and/or a video obtained by an image sensor in a camera mode and output it to the main processor 15.

A cable 600 having passed through the cable hole CAH of the bracket 13 may be connected to the main connector 17. Thus, the main circuit board 14 may be electrically connected to the display circuit board 300.

The battery 18 may be disposed so as not to overlap the main circuit board 14 in the third direction DR3. The battery 18 may overlap the battery hole BH of the bracket 13 in the third direction DR3.

In addition, the main circuit board 14 may be further equipped with a mobile communication module capable of transmitting and receiving radio signals with at least one of a base station, an external terminal, and/or a server in a mobile communication network. The radio signal may include various types of data according to transmission and reception of a voice signal, a video call signal, and/or a text/multimedia message.

The lower cover 12 may be disposed below the main circuit board 14 and the battery 18. The lower cover 12 may be fixed by being fastened to the bracket 13. The lower cover 12 may form the upper side surface, lower side surface, and bottom surface of the electronic device 10. The lower cover 12 may include plastic, metal, or both plastic and metal.

The lower cover 12 may include a second camera hole CMH2 through which the bottom surface of the camera 16 is exposed. The position of the camera 16 and the positions of the first and second camera holes CMH1 and CMH2 corresponding to the camera 16 are not limited to the embodiment illustrated in FIG. 2.

Next, the display device 100 according to one or more embodiments will be described.

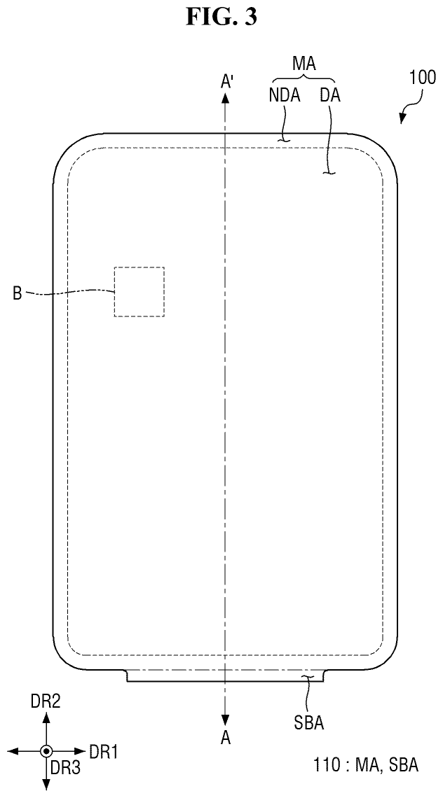

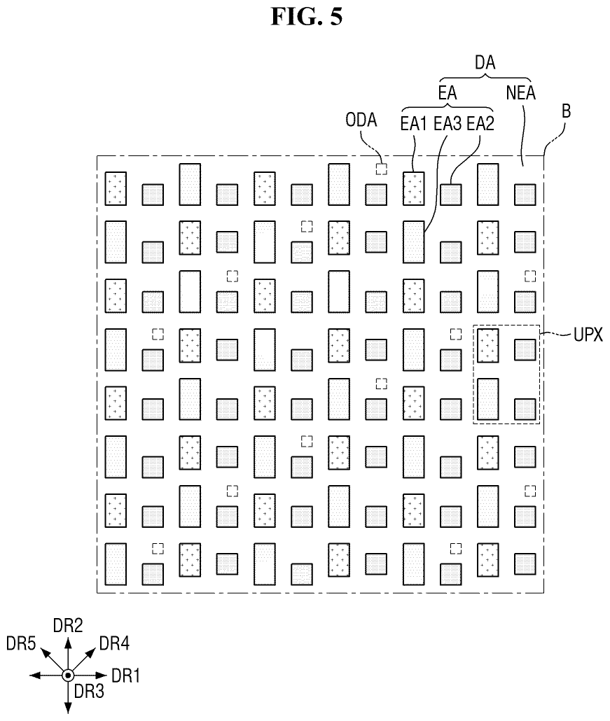

FIG. 3 is a plan view illustrating the display device of FIG. 2. FIG. 4 is a cross-sectional view taken along the line A-A′ of FIG. 3. FIG. 5 is a layout diagram illustrating a part B of FIG. 3.

FIGS. 3 and 4 illustrate the display device 100 with a part of the sub-region SBA in a bent state.

The display device 100 may be a light emitting display device such as an organic light emitting display using an organic light emitting diode (OLED), a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, the present disclosure is not limited thereto, and may be applied to a display device including an organic insulating material, an organic light emitting material, and a metal material.

The display device 100 may be formed to be flat, but is not limited thereto. For example, the display device 100 may include a curved portion formed at left and right ends and having a constant curvature or a varying curvature. In addition, the display device 100 may be formed to be flexible so that it can be curved, bent, folded, and/or rolled.

Referring to FIG. 3, at least one surface of the display device 100 includes the main region MA from which light for displaying an image is emitted.

The display area DA may, in a plan view, be formed in a rectangular shape having short sides extending in the first direction DR1 and long sides extending in the second direction DR2 crossing the first direction DR1. The corner where the short side extending in the first direction DR1 and the long side extending in the second direction DR2 meet may be rounded to have a suitable curvature (e.g., a predetermined curvature) or may be right-angled. The planar shape of the display area DA is not limited to the rectangular shape, and may be formed in another polygonal shape, a circular shape, or an elliptical shape.

The display area DA may occupy most of the main region MA. The display area DA may be disposed at the center of the main region MA.

Referring to FIG. 4, the display device 100 further includes the sub-region SBA protruding from one side of the main region MA.

The sub-region SBA may be a region protruding from the non-display area NDA of the main region MA to one side in the second direction DR2.

Because a part of the sub-region SBA is transformed into a bent shape, another part of the sub-region SBA may be disposed on the rear surface of the display device 100.

The display device 100 according to one or more embodiments includes a substrate 110, a circuit layer 120 disposed on the substrate 110, and an element layer 130 disposed on the circuit layer 120.

According to one or more embodiments, the display device 100 may further include an encapsulation layer 140 disposed on the element layer 130, and the touch sensor layer 150 disposed on the encapsulation layer 140. In addition, the display device 100 may further include a polarization layer 160 disposed on the touch sensor layer 150, in order to reduce reflection of external light.

The substrate 110 may include the main region MA corresponding to the display surface, and the sub-region SBA protruding from one side of the main region MA in the second direction DR2. The display driving circuit 200 may be disposed directly on the substrate 110. The substrate 110 and the circuit layer 120 may both be bent in the subregion SBA.

The main region MA of the substrate 110 may include the display area DA which is most of the center, and the non-display area NDA which is the periphery of the display area DA.

The sub-region SBA may protrude from one side of the main region MA in the second direction DR2.

Referring to FIG. 5, the display area DA includes emission areas EA, a non-emission area NEA which is a separation region between the emission areas EA, and light sensing areas ODA disposed in parts of the non-emission area NEA.

Each of the emission areas EA may be a unit that emits light in a wavelength band corresponding to one color of two or more different colors with a luminance corresponding to an image signal.

Each of the emission areas EA may have a rhombus planar shape or a rectangular planar shape. However, this is only an example, and the planar shape of the emission areas EA according to embodiments is not limited to that illustrated in FIG. 5. That is, the emission areas EA may have a polygonal shape such as a rhombus shape or a hexagonal shape other than a rectangular shape, a circular shape, or an elliptical shape in a plan view.

The emission areas EA may include a first emission area EA1 emitting light of a first color having a suitable wavelength band (e.g., a predetermined wavelength band), a second emission area EA2 emitting light of a second color having a wavelength band lower than that of the first color, and a third emission area EA3 emitting light of a third color having a wavelength band lower than that of the second color.

For example, the first color may be red having a wavelength band of approximately 600 nm to approximately 750 nm, the second color may be green having a wavelength band of approximately 480 nm to approximately 560 nm, and the third color may be blue having a wavelength band of approximately 370 nm to approximately 460 nm. However, this is only an example, and the wavelength bands of the first color, the second color, and the third color according to one or more embodiments are not limited thereto.

Because the emission areas EA include the first emission area EA1, the second emission area EA2, and the third emission area EA3, each of unit pixels UPX may be provided by a combination of one or more first emission areas EA1, one or more second emission areas EA2, and one or more third emission areas EA3 adjacent to each other from among the emission areas EA.

Each of the unit pixels UPX may be a unit for displaying various colors including white. That is, lights of various colors displayed by the unit pixels UPX may be implemented as a mixture of lights emitted from two or more emission areas EA included in each unit pixel UPX.

In a case where the first color of the first emission area EA1, the second color of the second emission area EA2, and the third color of the third emission area EA3 are red, green, and blue, respectively, the third emission area EA3 may have a larger width than the first emission area EA1, and the second emission area EA2 may have a smaller width than the first emission area EA1. However, this is merely an example, and the width of each of the emission areas EA is not limited to that illustrated in FIG. 5.

The first emission area EA1 and the third emission area EA3 may be alternately arranged along the first direction DR1 and/or the second direction DR2. Further, the second emission areas EA2 may be arranged side by side along the first direction DR1 and/or the second direction DR2. The second emission area EA2 may be disposed between the first emission area EA1 and the third emission area EA3 in a fourth direction DR4 or a fifth direction DR5. The fourth direction DR4 may be a diagonal direction between the first direction DR1 and the second direction DR2, and the fifth direction DR5 may be orthogonal to the fourth direction DR4.

In this case, each of the unit pixels UPX may include one first emission area EA1 and one third emission area EA3 adjacent to each other in the first direction DR1 or the second direction DR2, and two second emission areas EA2 adjacent thereto in the second direction DR2. However, this is only an example, and the arrangement pattern of the emission areas EA and the components of the unit pixel UPX according to one or more embodiments are not limited to those illustrated in FIG. 5.

According to one or more embodiments, the display area DA includes the light sensing areas ODA disposed in parts of the non-emission area NEA.

For example, the light sensing areas ODA may be disposed between the second emission areas EA2 having a relatively small width, in the second direction DR2. One or more emission areas EA may be disposed between the light sensing areas ODA in each of the first and second directions DR1 and DR2.

As shown in FIG. 4, according to one or more embodiments, the element layer 130 includes light emitting elements LE (see FIG. 8) respectively disposed in the emission areas EA, and the light sensing elements PD (see FIG. 8) respectively disposed in the light sensing areas ODA.

According to one or more embodiments, the circuit layer 120 may include the light emitting pixel drivers EPD (see FIG. 7) respectively electrically connected to the light emitting elements LE of the element layer 130, the light sensing pixel drivers DPD (see FIG. 7) respectively electrically connected to the light sensing elements PD of the element layer 130, the data lines DL (see FIG. 7) electrically connected to the light emitting pixel drivers EPD, and the read-out lines ROL (see FIG. 7) electrically connected to the light sensing pixel drivers DPD.

The encapsulation layer 140 may cover the element layer 130 and may extend into the non-display area NDA to be contact with the circuit layer 120. The encapsulation layer 140 may include a structure in which two or more inorganic layers and at least one organic layer are alternately stacked.

The touch sensor layer 150 may be disposed on the encapsulation layer 140 and may correspond to the main region MA. The touch sensor layer 150 may include touch electrodes for sensing a touch of a person or an object and may extend into the non-display area NDA to be in contact with the circuit layer 120.

A polarization layer 160 blocks external light reflected from the touch sensor layer 150, the encapsulation layer 140, the element layer 130, and the circuit layer 120, and the interfaces thereof, and this is to prevent the deterioration of visibility of an image due to external light reflection.

In one or more embodiments, as a part of the sub-region SBA is transformed into a bending shape, the display driving circuit 200 mounted in the sub-region SBA, and the display circuit board 300 connected to one side of the sub-region SBA may be disposed under the substrate 110.

The display driving circuit 200 may be electrically connected to the data lines DL of the circuit layer 120. The display driving circuit 200 may transmit the data signal of the light emitting pixel drivers EPD to the data lines DL based on control signals and power voltages supplied from the display circuit board 300.

The display driving circuit 200 may be provided as an integrated circuit (IC) and mounted on the sub-region SBA of the display device 100 by a chip on glass (COG) method, a chip on plastic (COP) method, or an ultrasonic method. However, this is only an example, and embodiments are not limited thereto. For example, the display driving circuit 200 may be mounted on the display circuit board 300.

One end of the display circuit board 300 may be attached onto pads disposed on one edge of the sub-region SBA of the display device 100 by using an anisotropic conductive film.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

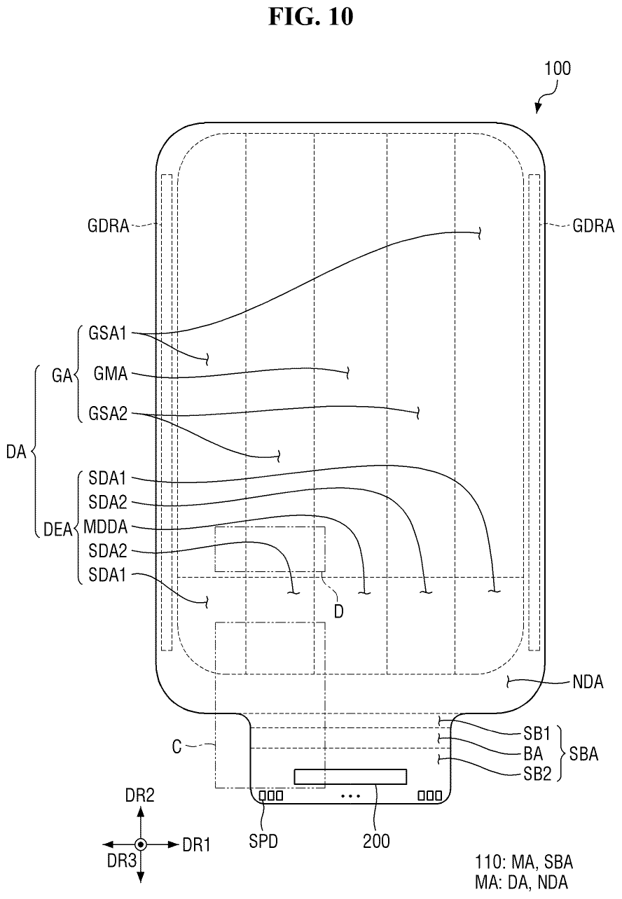

The display circuit board 300 may be connected to signal pads SPD (see FIG. 10) disposed on one side of the sub-region SBA.

The touch driving circuit 400 and the scanning driving circuit 500 may be mounted on the display circuit board 300.

The touch driving circuit 400 may be electrically connected to the touch sensor layer 150 of the display device 100.

The touch driving circuit 400 may apply a touch driving signal to driving lines of the touch sensor layer 150, and receive a touch sensing signal from sensing lines.

Further, the touch driving circuit 400 may detect charge variation amounts of capacitances based on the touch sensing signal, thereby determining whether a user has touched or approached. The user's touch means that an object such as a pen or a user's finger is in direct contact with the top surface of the cover window disposed on the touch sensor layer. The user's approach means that the object such as the pen or the user's finger hovers over the top surface of the cover window. The touch driving circuit 400 may output touch data including the user's touch coordinates to the main processor 15.

The scanning driving circuit 500 may be electrically connected to the read-out lines ROL of the circuit layer 120.

The scanning driving circuit 500 may collect light sensing signals of the light sensing elements PD disposed in the light sensing areas ODA of the main region MA through the light sensing pixel drivers DPD and the read-out lines ROL. Further, based on the collected light sensing signals, the scanning driving circuit 500 may output, to the main processor 15, scanning data about the shape of an object in contact with a screen by detecting differences in the amount of light reflected by the object in contact with the screen.

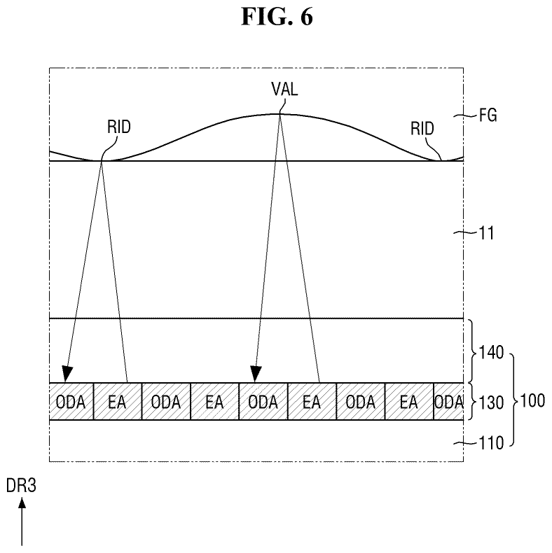

FIG. 6 is an diagram illustrating a scanning function by the light sensing areas shown in FIG. 5.

Referring to FIG. 6, the display device 100 according to one or more embodiments may include the light sensing elements PD (e.g., FIG. 8) disposed in the light sensing areas ODA, and thus may provide a scanning function to detect the shape of an object in contact with the screen.

The fingerprint of a user's finger FG in contact with the cover window 11 includes ridges RID and valleys VAL between the ridges RID. The ridges RID in the fingerprint are in contact with the cover window 11. However, the valleys VAL in the fingerprint are spaced (e.g., spaced apart) from the cover window 11. That is, the top surface of the cover window 11 facing the valleys VAL is in contact with air.

Light emitted from the emission areas EA may be reflected by the user's finger FG in contact with the cover window 11 and detected by the light sensing elements PD of the light sensing areas ODA. However, because the refractive index of the finger FG is different from that of the air, the amount of light reflected from the ridge RID may be different from the amount of light reflected from the valley VAL.

Accordingly, based on the difference in the amount of light incident on the light sensing elements PD, the ridge RID and the valley VAL of the fingerprint FG may be derived, so that the fingerprint FG pattern of the finger may be detected.

FIG. 7 is a block diagram showing a circuit layer of FIG. 4.

Referring to FIG. 7, the circuit layer 120 of the display device 100 according to one or more embodiments may include the light emitting pixel drivers EPD respectively corresponding to the emission areas EA of the display area DA, the light sensing pixel drivers DPD respectively corresponding to the light sensing areas ODA of the display area DA, the data lines DL electrically connected to the light emitting pixel drivers EPD, and the read-out lines ROL electrically connected to the light sensing pixel drivers DPD.

The display device 100 according to one or more embodiments may include the display driving circuit (e.g., data driver) 200 that transmits the data signal Vdata (see FIG. 8) of the light emitting pixel drivers EPD to the data lines DL, and the scanning driving circuit (e.g., read-out IC) 500 that collects the light sensing signals of the light sensing pixel drivers DPD through the read-out lines ROL.

The display device 100 according to one or more embodiments may further include a gate driving circuit (e.g., gate driver) 101 that supplies one or more gate signals to the light emitting pixel drivers EPD and the light sensing pixel drivers DPD, an emission control circuit (e.g., emission driver) 102 that supplies emission control signals EC (see FIG. 8) to the light emitting pixel drivers EPD, a power supply unit 700 that supplies various power and voltages to the light emitting pixel drivers EPD and the light sensing pixel drivers DPD, and a timing controller 800 that controls a drive timing.

The timing controller 800 receives an image signal supplied from the outside of the display device 100. The timing controller 800 may output image data DATA and a data control signal DCS to the display driving circuit 200. In addition, the timing controller 800 may generate a scan control signal SCS for controlling the operation timing of the gate driving circuit 101, and an emission control driving signal ECS for controlling the operation timing of the emission control circuit 102. For example, the timing controller 800 may generate the scan control signal SCS and the emission control driving signal ECS, output the scan control signal SCS to the gate driving circuit 101 through a scan control line, and output the emission control driving signal ECS to the emission control circuit 102 through an emission control driving line.

The display driving circuit 200 may convert the image data DATA into analog data voltages and output them to the data lines DL.

The gate driving circuit 101 may generate gate signals in response to the scan control signal SCS and sequentially output the gate signals to gate lines GL. The gate lines GL may include a scan write line GWL (see FIG. 8) for transmitting a scan write signal GW (see FIG. 8), a scan initialization line GIL (see FIG. 8) for transmitting a scan initialization signal GI (see FIG. 8), a gate control line GCL (see FIG. 8) for transmitting a gate control signal GC (see FIG. 8), a bias control line GBL (see FIG. 8) for transmitting a bias control signal GB (see FIG. 8), and a reset control line GRL (see FIG. 8) for transmitting a reset control signal GR (see FIG. 8).

The emission control circuit 102 may sequentially output the emission control signals EC (see FIG. 8) to the emission control lines ECL in response to the emission control driving signal ECS. The emission control signals EC of the emission control circuit 102 may have pulses of a first level voltage or a second level voltage. In one or more embodiments, the emission control circuit 102 may not be provided separately from the gate driving circuit 101 and may be incorporated into the gate driving circuit 101.

The power supply unit 700 may supply various types of power required to drive the light emitting pixel drivers EPD and the light sensing pixel drivers DPD.

For example, the power supply unit 700 may supply a first power ELVDD (see FIG. 8) and a second power ELVSS (see FIG. 8) for driving the light emitting elements LE, and a first initialization voltage VINT (see FIG. 8) and a second initialization voltage VAINT (see FIG. 8) for initializing the light emitting pixel drivers EPD.

In addition, the power supply unit 700 may further supply a reset voltage VRST (see FIG. 8) for resetting the light sensing pixel drivers DPD.

The scanning driving circuit 500 may be electrically connected to the light sensing elements PD through the read-out lines ROL and the light sensing pixel drivers DPD.

Each of the light sensing elements PD may generate a photocurrent corresponding to the amount of light incident on the light sensing element PD, and the scanning driving circuit 500 may detect the shape of a user's fingerprint based on the photocurrent of each of the light sensing elements PD.

The scanning driving circuit 500 may generate scanning data depending on the magnitude of photocurrent detected by the light sensing elements PD and transmit it to the main processor, and the main processor 15 may compare the scanning data with reference data and execute an application based on whether the scanning data matches the user's fingerprint.

FIG. 8 is an equivalent circuit diagram of the light emitting pixel driver and the light sensing pixel driver shown in FIG. 7.

Referring to FIG. 8, one of the light emitting elements LE of the element layer 130 may be electrically connected between one of the light emitting pixel drivers EPD of the circuit layer 120 and the second power ELVSS.

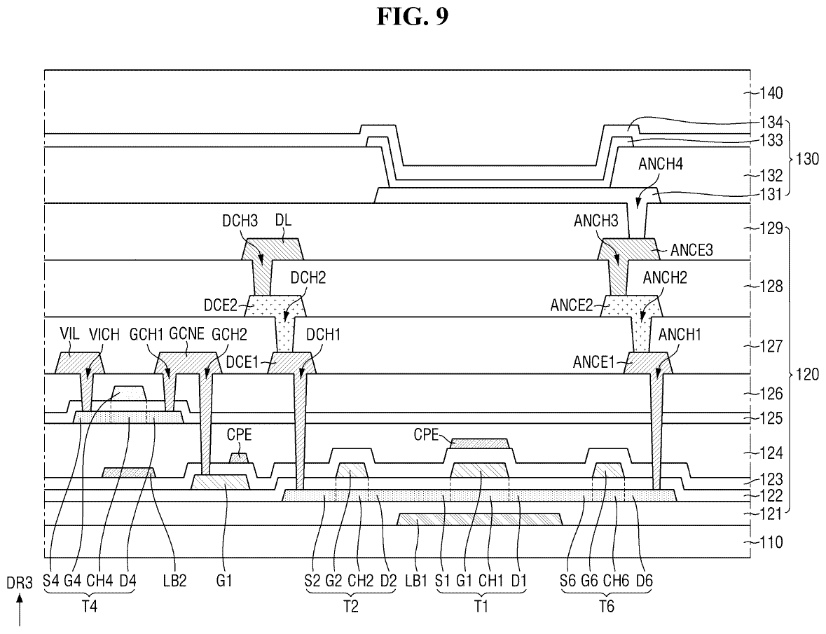

That is, an anode electrode 131 (see FIG. 9) of the light emitting element LE may be electrically connected to the light emitting pixel driver EPD, and a cathode electrode 134 (see FIG. 9) of the light emitting element LE may be applied with the second power ELVSS having a lower voltage level than the first power ELVDD.

A capacitor Cel connected in parallel with the light emitting element LE refers to a parasitic capacitance between the anode electrode 131 and the cathode electrode 134.

The circuit layer 120 may further include a first power line VDL for transmitting the first power ELVDD, a first initialization voltage line VIL for transmitting the first initialization voltage VINT, a second initialization voltage line VAIL for transmitting the second initialization voltage VAINT, and a bias power line VBL for transmitting a bias power VBS.

The circuit layer 120 may further include the scan write line GWL for transmitting the scan write signal GW, the scan initialization line GIL for transmitting the scan initialization signal GI, the emission control line ECL for transmitting the emission control signal EC, the gate control line GCL for transmitting the gate control signal GC, and the bias control line GBL for transmitting the bias control signal GB.

One light emitting pixel driver EPD of the circuit layer 120 may include a first transistor T1 configured to generate a driving current for driving the light emitting element LE, two or more transistors T2 to T8 electrically connected to the first transistor T1, and at least one capacitor PC1.

The first transistor T1 is connected in series with the light emitting element LE between the first power ELVDD and the second power ELVSS.

That is, the first electrode (e.g., the source electrode) of the first transistor T1 may be electrically connected to the first power line VDL through the fifth transistor T5. Further, the second electrode (e.g., the drain electrode) of the first transistor T1 may be electrically connected to the anode electrode 131 of the light emitting element LE through the sixth transistor T6.

The first electrode of the first transistor T1 may be electrically connected to the data line DL through a second transistor T2.

The gate electrode of the first transistor T1 may be electrically connected to the first power line VDL through the first capacitor PC1. That is, the first capacitor PC1 may be electrically connected between the gate electrode of the first transistor T1 and the first power line VDL.

Accordingly, the potential of the gate electrode of the first transistor T1 may be maintained by the first power ELVDD of the first power line VDL.

Further, when the data signal Vdata of the data line DL is transmitted to the first electrode of the first transistor T1 through the turned-on second transistor T2, the voltage difference corresponding to the data signal Vdata and the first power ELVDD may be generated between the gate electrode of the first transistor T1 and the first electrode of the first transistor T1.

In this case, when the voltage difference between the gate electrode of the first transistor T1 and the first electrode of the first transistor T1, i.e., the gate-source voltage difference becomes equal to or greater than a threshold voltage, the first transistor T1 may be turned on, thereby generating a drain-source current of the first transistor T1 corresponding to the data signal Vdata.

Then, when the fifth transistor T5 and the sixth transistor T6 are turned on, the first transistor T1 may be connected in series with the light emitting element LE between the first power line VDL and a second power line VSL. Accordingly, the drain-source current of the first transistor T1 corresponding to the data signal Vdata may be supplied as a driving current of the light emitting element LE.

Accordingly, the light emitting element LE may emit light having a luminance corresponding to the data signal Vdata.

In one or more embodiments, the first transistor T1 may include a second gate electrode connected to the first power line VDL.

The second transistor T2 may be electrically connected between the first electrode of the first transistor T1 and the data line DL. The second transistor T2 may be turned on by the scan write signal GW of the scan write line GWL.

The third transistor T3 may be electrically connected between the gate electrode of the first transistor T1 and the second electrode of the first transistor T1. The third transistor T3 may be turned on by the gate control signal GC of the gate control line GCL and may connect the gate electrode of the first transistor T1 with the second electrode of the first transistor T1. As such, when the third transistor T3 is turned on, the first transistor T1 may act as a diode (e.g., the first transistor T1 may be diode-connected).

The fourth transistor T4 may be connected between the gate electrode of the first transistor T1 and the first initialization voltage line VIL. The fourth transistor T4 may be turned on by the scan initialization signal GI of the scan initialization line GIL and may initialize the gate electrode of the first transistor T1.

The third transistor T3 and the fourth transistor T4 may be provided as N-type MOSFETs and may be dual gate transistors.

The fifth transistor T5 may be electrically connected between the first electrode of the first transistor T1 and the first power line VDL.

The sixth transistor T6 may be electrically connected between the second electrode of the first transistor T1 and the anode electrode 131 of the light emitting element LE.

The fifth transistor T5 and the sixth transistor T6 may be turned on by the emission control signal EC of the emission control line ECL.

The seventh transistor T7 may be electrically connected between the anode electrode 131 of the light emitting element LE and the second initialization voltage line VAIL. The seventh transistor T7 may be turned on by the bias control signal GB of the bias control line GBL.

The eighth transistor T8 may be connected between the first electrode of the first transistor T1 and the bias power line VBL.

The eighth transistor T8 may be turned on by the bias control signal GB of the bias control line GBL.

From among the first to eighth transistors T1 to T8, the transistors T1, T2, and T5 to T8 other than the third and fourth transistor T3 and T4 may be provided as P-type MOSFETs.

In addition, one of the light sensing elements PD of the element layer 130 may be electrically connected between an element output node NOP of one of the light sensing pixel drivers DPD of the circuit layer 120 and the second power ELVSS.

The circuit layer 120 may further include the reset control line GRL for transmitting the reset control signal GR for initiating a reset of the light sensing pixel drivers DPD, a reset voltage line VRL for transmitting the reset voltage VRST for resetting the light sensing pixel drivers DPD, and the read-out line ROL electrically connecting the light sensing pixel drivers DPD to the scanning driving circuit 500.

Each of the light sensing pixel drivers DPD may include at least one transistor from among T9, T10, and T11.

The light sensing element PD may be a photoelectric conversion element that converts incident light into an electrical signal by generating a photocurrent corresponding to the amount of the incident light, and outputs a light sensing signal.

The light sensing element PD may be a photodiode including a sensing anode electrode, a sensing cathode electrode, and a photoelectric conversion layer disposed between the sensing anode electrode and the sensing cathode electrode.

The light sensing element PD may be a phototransistor or an inorganic photodiode formed of a p-n type or p-i-n type inorganic material. Alternatively, the photoelectric conversion element PD may also be an organic photodiode including an electron donating material generating donor ions and an electron accepting material generating acceptor ions.

When light is incident on the light sensing element PD, the photoelectric conversion layer may react to the incident light to generate photocharges, and the photocharges generated in the photoelectric conversion layer may move, thereby generating a photocurrent between the sensing anode electrode and the sensing cathode electrode.

As one example, photocharges generated in the photoelectric conversion layer by light incident on the light sensing element PD may be accumulated in the sensing anode electrode. In addition, the potential of the element output node NOP electrically connected to the sensing anode electrode may be increased by the photocharges accumulated in the sensing anode electrode. When the light sensing element PD and the read-out line ROL are connected to the element output node NOP by the turn-on of ninth and eleventh transistors T9 and T11, a sensing voltage may be accumulated at a node N3 between the read-out line ROL and the eleventh transistor T11 in proportion to the voltage of the element output node NOP where charges are accumulated.

The ninth transistor T9 may include a gate electrode electrically connected to the element output node NOP, and may be electrically connected between the second initialization voltage line VAIL and the eleventh transistor T11.

The ninth transistor T9 may be a source follower amplifier that generates a source-drain current in proportion to the amount of electric charges of the element output node NOP inputted to the gate electrode thereof.

That is, when the potential of the element output node NOP is increased by the photocharges accumulated in the light sensing element PD, and the difference voltage between the second initialization voltage VAINT and the potential of the element output node NOP becomes equal to or greater than the threshold voltage of the ninth transistor T9, the ninth transistor T9 may be turned on. In this case, a light sensing signal corresponding to the difference voltage between the second initialization voltage VAINT and the potential of the element output node NOP may be generated by the turned-on ninth transistor T9.

Although FIG. 8 illustrates that the first electrode of the ninth transistor T9 is connected to the second initialization voltage line VAIL, the present disclosure is not limited to the illustration of FIG. 8. That is, the first electrode of the ninth transistor T9 may be connected to one of the first power line VDL and the first initialization voltage line VIL, rather than the second initialization voltage line VAIL.

The tenth transistor T10 may be electrically connected between the element output node NOP and the reset voltage line VRL, and may be turned on by the reset control signal GR of the reset control line GRL. Accordingly, when the tenth transistor T10 is turned on by the reset control signal GR, the potential of the element output node NOP may be reset to the reset voltage VRST of the reset voltage line VRL.

The eleventh transistor T11 may be electrically connected between the second electrode of the ninth transistor T9 and the read-out line ROL, and may be turned on by the scan write signal GW of the scan write line GWL. Accordingly, the source-drain current, i.e., the light sensing signal, of the ninth transistor T9 may be transmitted to the read-out line ROL through the eleventh transistor T11 turned on by the scan write signal GW.

The ninth transistor T9 and the eleventh transistor T11 may be provided as P-type MOSFETs, and the tenth transistor T10 may be provided as an N-type MOSFET.

FIG. 9 is a cross-sectional view illustrating a first transistor, a second transistor, a fourth transistor, a sixth transistor, and one light emitting element of FIG. 8.

Referring to FIG. 9, the circuit layer 120 of the display device 100 according to one or more embodiments may include a buffer layer 121 that covers a first light blocking layer LB1 on the substrate 110, a first semiconductor layer CH1, S1, D1, CH2, S2, D2, CH6, S6, and D6 disposed on the buffer layer 121, a first gate insulating layer 122 that covers the first semiconductor layer CH1, S1, D1, CH2, S2, D2, CH6, S6, and D6 and the buffer layer 121, a first gate conductive layer G1, G2, and G6 disposed on the first gate insulating layer 122, a second gate insulating layer 123 that covers the first gate conductive layer G1, G2, and G6 and the first gate insulating layer 122, a second gate conductive layer CPE and LB2 disposed on the second gate insulating layer 123, an additional interlayer insulating layer 124 that covers the second gate conductive layer CPE and LB2 and the second gate insulating layer 123, a second semiconductor layer CH4, S4, and D4 disposed on the additional interlayer insulating layer 124, a third gate insulating layer 125 that covers the second semiconductor layer CH4, S4, and D4 and the additional interlayer insulating layer 124, a third gate conductive layer G4 disposed on the third gate insulating layer 125, an interlayer insulating layer 126 that covers the third gate conductive layer G4 and the third gate insulating layer 125, a first source-drain conductive layer ANCE1, DCE1, GCNE, and VIL disposed on the interlayer insulating layer 126, a first planarization layer 127 that covers the first source-drain conductive layer ANCE1, DCE1, GCNE, and VIL and the interlayer insulating layer 126, a second source-drain conductive layer ANCE2 and DCE2 disposed on the first planarization layer 127, a second planarization layer 128 that covers the second source-drain conductive layer ANCE2 and DCE2 and the first planarization layer 127, a third source-drain conductive layer ANCE3 and DL disposed on the second planarization layer 128, and a third planarization layer 129 that covers the third source-drain conductive layer ANCE3 and DL and the second planarization layer 128.

The first transistor T1 may include the channel portion CH1, the source portion S1, and the drain portion D1 formed of the first semiconductor layer on the buffer layer 121, and the gate electrode G1 disposed on the first gate insulating layer 122 and overlapping the channel portion CH1 in the third direction DR3 (e.g., a thickness direction of the substrate 110.

The channel portion CH1 of the first transistor T1 may overlap the first light blocking layer LB1 on the substrate 110 in the third direction DR3.

The second transistor T2 may include the channel portion CH2, the source portion S2, and the drain portion D2 formed of the first semiconductor layer on the buffer layer 121, and the gate electrode G2 disposed on the first gate insulating layer 122 and overlapping the channel portion CH2 in the third direction DR3.

The sixth transistor T6 may include the channel portion CH6, the source portion S6, and the drain portion D6 formed of the first semiconductor layer on the buffer layer 121, and the gate electrode G6 disposed on the first gate insulating layer 122 and overlapping the channel portion CH6 in the third direction DR3.

The source portion S2 of the second transistor T2 may be electrically connected to the data line DL through a first data connection electrode DCE1 and a second data connection electrode DCE2.

The first data connection electrode DCE1 may be disposed on the interlayer insulating layer 126, and may be electrically connected to the source portion S2 of the second transistor T2 through a first data contact hole DCH1 penetrating the interlayer insulating layer 126, the third gate insulating layer 125, the additional interlayer insulating layer 124, the second gate insulating layer 123, and the first gate insulating layer 122.

The second data connection electrode DCE2 may be disposed on the first planarization layer 127, and may be electrically connected to the first data connection electrode DCE1 through a second data contact hole DCH2 penetrating the first planarization layer 127.

The data line DL may be disposed on the second planarization layer 128, and may be electrically connected to the second data connection electrode DCE2 through a third data contact hole DCH3 penetrating the second planarization layer 128.

The drain portion D2 of the second transistor T2 may be connected to the source portion S1 of the first transistor T1.

The drain portion D1 of the first transistor T1 may be connected to the source portion S6 of the sixth transistor T6.

The drain portion D6 of the sixth transistor T6 may be electrically connected to the anode electrode 131 through a first anode connection electrode ANCE1, a second anode connection electrode ANCE2, and a third anode connection electrode ANCE3.

The first anode connection electrode ANCE1 may be disposed on the interlayer insulating layer 126, and may be electrically connected to the drain portion D6 of the sixth transistor T6 through a first anode contact hole ANCH1 penetrating the interlayer insulating layer 126, the third gate insulating layer 125, the additional interlayer insulating layer 124, the second gate insulating layer 123, and the first gate insulating layer 122.

The second anode connection electrode ANCE2 may be disposed on the first planarization layer 127, and may be electrically connected to the first anode connection electrode ANCE1 through a second anode contact hole ANCH2 penetrating the first planarization layer 127.

The third anode connection electrode ANCE3 may be disposed on the second planarization layer 128, and may be electrically connected to the second anode connection electrode ANCE2 through a third anode contact hole ANCH3 penetrating the second planarization layer 128.

The anode electrode 131 may be disposed on a third planarization layer 129, and may be electrically connected to the third anode connection electrode ANCE3 through a fourth anode contact hole ANCH4 penetrating the third planarization layer 129.

The first capacitor PC1 may be provided by an overlapping region between a capacitor electrode CPE disposed on the second gate insulating layer 123 and the gate electrode G1 of the first transistor T1.

The fourth transistor T4 may include a channel portion CH4, a source portion S4, and a drain portion D4 formed of the second semiconductor layer on the additional interlayer insulating layer 124, and a gate electrode G4 disposed on the third gate insulating layer 125 and overlapping the channel portion CH4 in the third direction DR3.

The channel portion CH4 of the fourth transistor T4 may overlap a second light blocking layer LB2 on the second gate insulating layer 123 in the third direction DR3.

The source portion S4 of the fourth transistor T4 may be electrically connected to the first initialization voltage line VIL on the interlayer insulating layer 126 through a hole VICH penetrating the interlayer insulating layer 126 and the third gate insulating layer 125.

The drain portion D4 of the fourth transistor T4 may be electrically connected to the gate electrode G1 of the first transistor T1 through a gate connection electrode GCNE on the interlayer insulating layer 126.

The gate connection electrode GCNE may be electrically connected to the drain portion D4 of the fourth transistor T4 through a first gate contact hole GCH1 penetrating the interlayer insulating layer 126 and the third gate insulating layer 125.

The gate connection electrode GCNE may be electrically connected to the gate electrode G1 of the first transistor T1 through a second gate contact hole GCH2 penetrating the interlayer insulating layer 126, the third gate insulating layer 125, the additional interlayer insulating layer 124, and the second gate insulating layer 123.

Because the third transistor T3 and the tenth transistor T10 are similar in structure to the fourth transistor T4, and the fifth transistor T5, the seventh transistor T7, the ninth transistor T9, and the eleventh transistor T11 are similar in structure to the second transistor T2 and the sixth transistor T6, the redundant description is omitted below.

In addition, the circuit layer 120 of the display device 100 according to one or more embodiments may further include a wire electrically connected between some of the data lines DL and the display driving circuit 200 and disposed in the display area DA, and a wire electrically connected between some of the read-out lines ROL and the scanning driving circuit 500 and disposed in the display area DA, in order to reduce the width of the non-display area NDA.

In one or more embodiments, the light emitting layer 130 includes the anode electrode 131 connected to the third anode connection electrode ANCE3 through the fourth anode contact hole ANCH4 penetrating the third planarization layer 129, a pixel defining layer (PDL) 132 disposed on the third planarization layer 129 and covers the edges of the anode electrode 131, an intermediate layer (e.g., a light emitting layer) 133 that directly contacts the anode electrode 131 and also overlaps the pixel defining layer 132 at the edges, and the cathode electrode 134 that covers the intermediate layer 133 and the pixel defining layer 132. The encapsulation layer 140 may be disposed on the element layer 130.

FIG. 10 is a plan view illustrating the substrate of FIG. 2 according to one or more embodiments.

Referring to FIG. 10, the substrate 110 of the display device 100 according to one or more embodiments may include the main region MA corresponding to the display surface, and the sub-region SBA protruding from one side of the main region MA.

The main region MA may include the display area DA disposed at most of the center, and the non-display area NDA disposed at the periphery to be around (e.g., to surround) the display area DA.

The display area DA may include a bypass area DEA disposed on one side adjacent to the sub-region SBA, and a general area GA disposed in the remaining area excluding the bypass area DEA.

The bypass area DEA may include a bypass middle area MDDA disposed at the center in the first direction DR1, a first bypass side area SDA1 parallel to the bypass middle area MDDA in the first direction DR1 and in contact with the non-display area NDA, and a second bypass side area SDA2 disposed between the bypass middle area MDDA and the first bypass side area SDA1.

The first bypass side area SDA1 may be disposed adjacent to the bent corner of the substrate 110 as compared to the bypass middle area MDDA and the second bypass side area SDA2.

The first bypass side area SDA1 and the second bypass side area SDA2 may be disposed between one side of the bypass middle area MDDA in the first direction DR1 and the non-display area NDA, and between the other side of the bypass middle area MDDA in the first direction DR1 and the non-display area NDA.

The general area GA may include a general middle area GMA connected to the bypass middle area MDDA of the bypass area DEA in the second direction DR2, a first general side area GSA1 connected to the first bypass side area SDA1 in the second direction DR2, and a second general side area GSA2 connected to the second bypass side area SDA2 in the second direction DR2.

The non-display area NDA may include a gate driving circuit area GDRA in which the gate driving circuit 101 and the emission control circuit 102 are disposed.

The gate driving circuit area GDRA may be disposed in a portion of the non-display area NDA adjacent to at least one side of the display area DA in the first direction DR1.

The sub-region SBA may include a bending region BA that is transformed into a bending shape, a first sub-region SB1 disposed between one side of the bending region BA and the main region MA, and a second sub-region SB2 connected to the other side of the bending region BA.

When the bending region BA is transformed into a bending shape, the second sub-region SB2 is disposed below the substrate 110 and overlaps the main region MA.

The display driving circuit 200 may be disposed in the second sub-region SB2.

The signal pads SPD bonded to the circuit board 300 may be disposed at one edge of the second sub-region SB2.

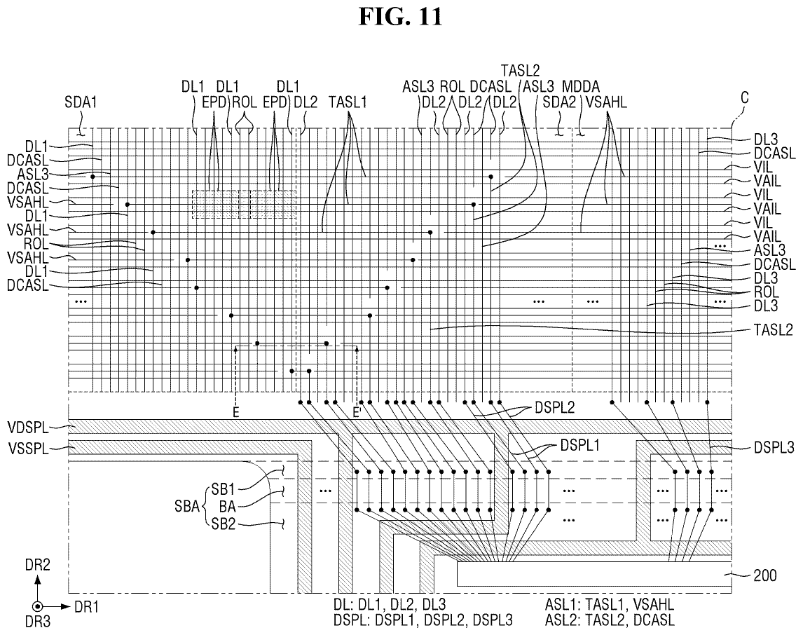

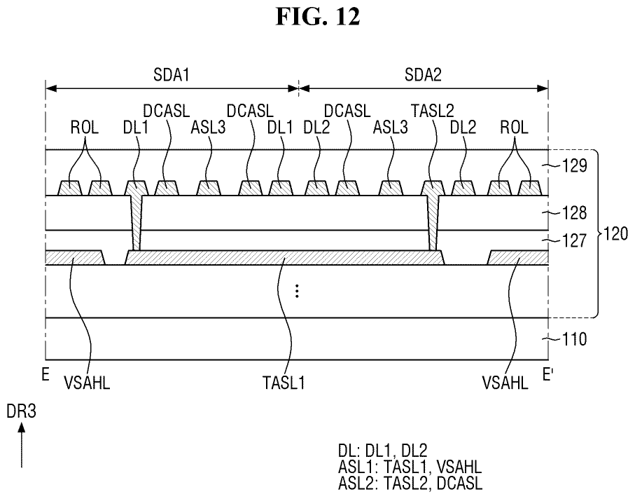

FIG. 11 is a layout diagram illustrating a part C of FIG. 10. FIG. 12 is a cross-sectional view taken along the line E-E′ of FIG. 11.

Referring to FIG. 11, the circuit layer 120 of the display device 100 according to one or more embodiments may include the light emitting pixel drivers EPD electrically connected to the light emitting elements LE of the element layer 130 and arranged side by side along the first and second directions DR1 and DR2, the data lines DL extending in the second direction DR2 and transmitting the data signal Vdata (see FIG. 8) to the light emitting pixel drivers EPD, first auxiliary lines ASL1 extending in the first direction DR1, second auxiliary lines ASL2 extending in the second direction DR2 and adjacent to the data lines DL, and third auxiliary lines ASL3 extending in the second direction DR2 and disposed between the second auxiliary lines in the first direction DR1.

According to one or more embodiments, the circuit layer 120 may further include the light sensing pixel drivers DPD that are respectively electrically connected to the light sensing elements PD of the element layer 130.

In this case, the circuit layer 120 may further include the read-out lines ROL extending in the second direction DR2, electrically connected to the light sensing pixel driver DPD, and transmitting light sensing signals.

In one example, the read-out lines ROL may be arranged two by two between the data lines DL in the first direction DR1. That is, one of two adjacent read-out lines ROL may be adjacent to one data line DL on one side of the first direction DR1, and the other of the two adjacent read-out lines ROL may be adjacent to another data line DL on the other side of the first direction DR1.

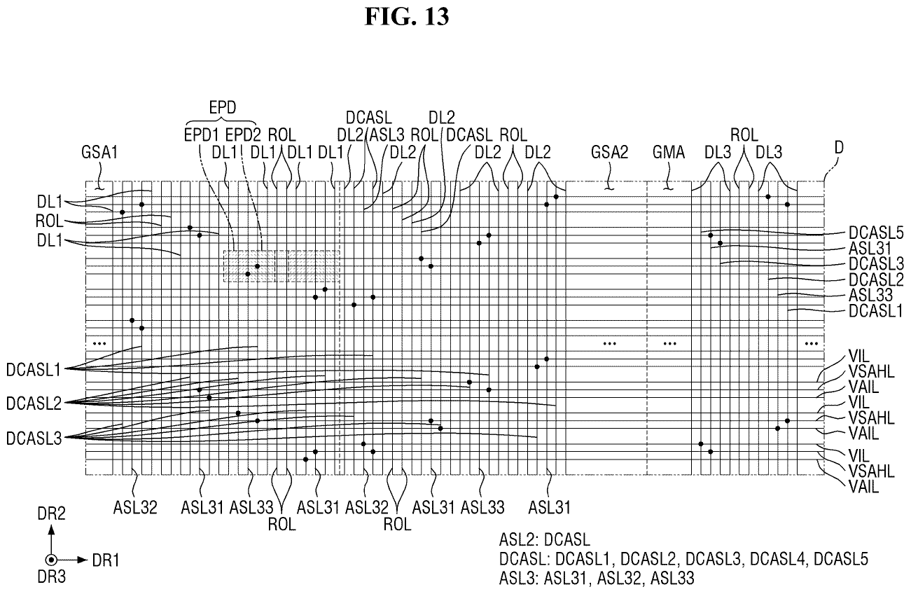

The light emitting pixel drivers EPD may include a first light emitting pixel driver EPD1 (see FIG. 13) and a second light emitting pixel driver EPD2 (see FIG. 13) that are adjacent to each other.

The first light emitting pixel driver EPD1 (see FIG. 13) and the second light emitting pixel driver EPD2 (see FIG. 13) may overlap one first auxiliary line ASL1.

The first light emitting pixel driver EPD1 may overlap one data line DL and one second auxiliary line ASL2.

The second light emitting pixel driver EPD2 may overlap another data line DL and another second auxiliary line ASL2.

One third auxiliary line ASL3 may be disposed adjacent to a boundary between the first light emitting pixel driver EPD1 and the second light emitting pixel driver EPD2.

The first light emitting pixel driver EPD1 and the second light emitting pixel driver EPD2 may be mutually symmetrical with respect to the boundary between the first light emitting pixel driver EPD1 and the second light emitting pixel driver EPD2.

That is, in the first light emitting pixel driver EPD1, one second auxiliary line ASL2 may be disposed between one data line DL and one third auxiliary line ASL3.

In addition, in the second light emitting pixel driver EPD2, another second auxiliary line ASL2 may be disposed between another data line DL and one third auxiliary line ASL3.

According to one or more embodiments, the data lines DL may include a first data line DL1 disposed in the first bypass side area SDA1 and a second data line DL2 disposed in the second bypass side area SDA2.

The first auxiliary lines ASL1 may include a first bypass auxiliary line TASL1 electrically connected to the first data line DL1 of the first bypass side area SDA1.

The second auxiliary lines ASL2 may include a second bypass auxiliary line TASL2 adjacent to the second data line DL2 of the second bypass side area SDA2 and electrically connected to the first bypass auxiliary line TASL1.

According to one or more embodiments, the circuit layer 120 may further include data supply lines DSPL disposed in the non-display area NDA and electrically connected to the display driving circuit 200 and the data lines DL.

The data supply lines DSPL may include a first data supply line DSPL1 that transmits the data signal of the first data line DL1, and a second data supply line DSPL2 that transmits the data signal of the second data line DL2.

According to one or more embodiments, the data supply lines DSPL may extend to the second bypass side area SDA2 and the bypass middle area MDDA.

Accordingly, the first data supply line DSPL1 may extend to the second bypass auxiliary line TASL2 of the second bypass side area SDA2, and may be electrically connected to the first data line DL1 through the second bypass auxiliary line TASL2 and the first bypass auxiliary line TASL1.

On the other hand, the second data supply line DSPL2 may extend to the second bypass side area SDA2, and may be electrically connected to the second data line DL2 directly.

The data lines DL may further include a third data line DL3 disposed in the bypass middle area MDDA, and the data supply lines DSPL may further include a third data supply line DSPL3 transmitting a data signal of the third data line DL3.

The third data supply line DSPL3 may extend to the bypass middle area MDDA, and may be directly electrically connected to the third data line DL3.

In this way, because the first data supply line DSPL1 extends not to the first data line DL1 of the first bypass side area SDA1 but to the second bypass auxiliary line TASL2 of the second bypass side area SDA2, the extension length of the first data supply line DSPL1 may be shortened. As a result, the width of the area required for the disposition of the data supply lines DSPL may be reduced, so that the width of the non-display area NDA may be reduced.

In addition, because the data supply lines DSPL are not disposed in a portion of the non-display area NDA located between the bent corner of the substrate 110 and the first bypass side area SDA1, the width of the non-display area NDA can be further reduced.

The first bypass auxiliary line TASL1 extends from the second bypass auxiliary line TASL2 to the first data line DL1.

The second bypass auxiliary line TASL2 extends from the first data supply line DSPL1 of the non-display area NDA to the first bypass auxiliary line TASL1.

In this way, as the first bypass auxiliary line TASL1 and the second bypass auxiliary line TASL2 are limitedly arranged in the bypass area DEA, the ends of the first bypass auxiliary line TASL1 and the ends of the second bypass auxiliary line TASL2 are arranged with regularity. Accordingly, visibility of the first bypass auxiliary line TASL1 and the second bypass auxiliary line TASL2 may be increased.

To prevent this, the first auxiliary lines ASL1 may further include not only the first bypass auxiliary line TASL1 but also power auxiliary horizontal lines VSAHL. Also, the second auxiliary lines ASL2 may further include not only the second bypass auxiliary lines TASL2 but also auxiliary vertical lines DCASL.

In other words, the remainder of the first auxiliary lines ASL1 excluding the first bypass auxiliary line TASL1 may be the power auxiliary horizontal lines VSAHL.

In addition, the remainder of the second auxiliary lines ASL2 excluding the second bypass auxiliary line TASL2 may be the auxiliary vertical lines DCASL.

Two of the power auxiliary horizontal lines VSAHL may extend from both ends of the first bypass auxiliary line TASL1 to the non-display area NDA.

One of the auxiliary vertical lines DCASL may extend from one end of the second bypass auxiliary line TASL2 to the non-display area NDA in a direction away from the sub-region SBA.

Accordingly, a part of each second data line DL2 is adjacent to the second bypass auxiliary line TASL2, and the other part of the second data line DL2 may be adjacent to the one auxiliary vertical line DCASL extending from the one end of the second bypass auxiliary line TASL2.

Because the second bypass auxiliary line TASL2 is disposed only in the second bypass side area SDA2, each of the first data line DL1 in the first bypass side area SDA1 and the third data line DL3 in the bypass middle area MDDA may be adjacent to the auxiliary vertical line DCASL.

The circuit layer 120 may further include a first power supply line VDSPL and a second power supply line VSSPL that respectively transmit the first power ELVDD (see FIG. 8) and the second power ELVSS (see FIG. 8) for driving the light emitting elements LE (see FIG. 8).

The first power supply line VDSPL and the second power supply line VSSPL may be disposed in the non-display area NDA and may extend to the sub-region SBA.

The first power supply line VDSPL may be electrically connected to a first power pad for transmitting the first power ELVDD (see FIG. 8) from among the signal pads SPD (see FIG. 10) disposed in the second sub-region SB2.

The second power supply line VSSPL may be electrically connected to a second power pad for transmitting the second power ELVSS (see FIG. 8) from among the signal pads SPD (see FIG. 10) disposed in the second sub-region SB2.

The power auxiliary horizontal lines VSAHL may be electrically connected to the second power supply line VSSPL and may transmit the second power ELVSS (see FIG. 8).

According to one or more embodiments, each of the auxiliary vertical lines DCASL may transmit one of the second power ELVSS (see FIG. 8), the first initialization voltage VINT (see FIG. 8), and the second initialization voltage VAINT (see FIG. 8).

In addition, each of the third auxiliary lines ASL3 may transmit one of the second power ELVSS (see FIG. 8), the first initialization voltage VINT (see FIG. 8), and the second initialization voltage VAINT (see FIG. 8).

As such, by electrically connecting each of the auxiliary vertical lines DCASL and the third auxiliary lines ASL3 to one of the power auxiliary horizontal line VSAHL, the first initialization voltage line VIL, and the second initialization voltage line VAIL, the second power ELVSS (see FIG. 8), the first initialization voltage VINT (see FIG. 8), and the second initialization voltage VAINT (see FIG. 8) may be transmitted to the display area DA through mesh-shaped wires having a relatively low resistance.

This will be described later with reference to FIG. 13.

Referring to FIG. 12, the data lines DL, the second auxiliary lines ASL2, the third auxiliary lines ASL3, and the read-out lines ROL may be disposed on at least one insulating layer (e.g., the first planarization layer 127 and the second planarization layer 128) that covers the first auxiliary lines ASL1.

For example, the first auxiliary lines ASL1 may be disposed in (or at) the first source-drain conductive layer on the interlayer insulating layer 126, and covered with the first planarization layer 127.

The data lines DL, the second auxiliary lines ASL2, the third auxiliary lines ASL3, and the read-out lines ROL may be disposed in (or at) the third source-drain conductive layer on the second planarization layer 128.

In this case, the first data line DL1 may be electrically connected to the first bypass auxiliary line TASL1 through a contact hole penetrating the second planarization layer 128 and the first planarization layer 127.

The second bypass auxiliary line TASL2 may also be electrically connected to the first bypass auxiliary line TASL1 through a contact hole penetrating the second planarization layer 128 and the first planarization layer 127.

FIG. 13 is a plan view showing a part D of FIG. 10 according to one or more embodiments.

As shown in FIG. 13, according to one or more embodiments, the auxiliary vertical lines DCASL, which are the remainder of the second auxiliary lines ASL2 excluding the second bypass auxiliary line TASL2, may include a first auxiliary vertical line DCASL1 for transmitting the second power ELVSS (see FIG. 8), a second auxiliary vertical line DCASL2 for transmitting the first initialization voltage VINT (see FIG. 8), and a third auxiliary vertical line DCASL3 for transmitting the second initialization voltage VAINT (see FIG. 8).

In addition, according to one or more embodiments, the third auxiliary lines ASL3 disposed between the second auxiliary lines ASL2 may include a power additional line ASL31 for transmitting the second power ELVSS (see FIG. 8), a first initialization voltage additional line ASL32 for transmitting the first initialization voltage VINT (see FIG. 8), and a second initialization voltage additional line ASL33 for transmitting the second initialization voltage VAINT (see FIG. 8).

In one example, the first initialization voltage additional line ASL32 and the second initialization voltage additional line ASL33 may be repeatedly arranged. Alternatively, the first initialization voltage additional line ASL32, the power additional line ASL31, the second initialization voltage additional line ASL33, and the power additional line ASL31 may be repeatedly arranged. However, this is merely an example, and the arrangement of the third auxiliary lines ASL3 is not limited to the illustration of FIG. 13.

Each of the third auxiliary lines ASL3 may be disposed between two second auxiliary lines ASL2.

The third auxiliary line ASL3 and two second auxiliary lines ASL2 adjacent to both sides thereof may transmit the data signal Vdata (see FIG. 8) of the first data line DL1, the second power ELVSS (see FIG. 8), and different voltages of the first initialization voltage VINT (see FIG. 8) and the second initialization voltage VAINT (see FIG. 8). However, this is merely an example, and the arrangement of the second auxiliary lines ASL2 is not limited to the illustration of FIG. 13.

As shown in FIG. 13, according to one or more embodiments, two electrical connections may be provided between wires in the first direction DR1 and wires in the second direction DR2, for each pair of adjacent light emitting pixel drivers EPD with the third auxiliary line ASL3 interposed therebetween from among the light emitting pixel drivers EPD.

The light emitting pixel drivers EPD may include the first light emitting pixel driver EPD1 and the second light emitting pixel driver EPD2 that are adjacent in the first direction DR1.

One of the first auxiliary lines ASL1 extending in the first direction DR1 may overlap the first light emitting pixel driver EPD1 and the second light emitting pixel driver EPD2.

The second auxiliary lines ASL2 extending in the second direction DR2 and adjacent to the data lines DL may include one second auxiliary line ASL2 overlapping the first light emitting pixel driver EPD1 and another second auxiliary line ASL2 overlapping the second light emitting pixel driver EPD2.

The third auxiliary lines ASL3 extending in the second direction DR2 may include one third auxiliary line ASL3 adjacent the boundary between the first light emitting pixel driver EPD1 and the second light emitting pixel driver EPD2. One third auxiliary line ASL3 may be disposed between one second auxiliary line ASL2 and another second auxiliary line ASL2.

By each electrical connection between the wires in the first direction DR1 and the wires in the second direction DR2, one of one first auxiliary line ASL1 (TASL1 and VSAHL in FIG. 11), the first initialization voltage line VIL, and the second initialization voltage line VAIL may be electrically connected to one of the second auxiliary line ASL2 and the third auxiliary line ASL3.

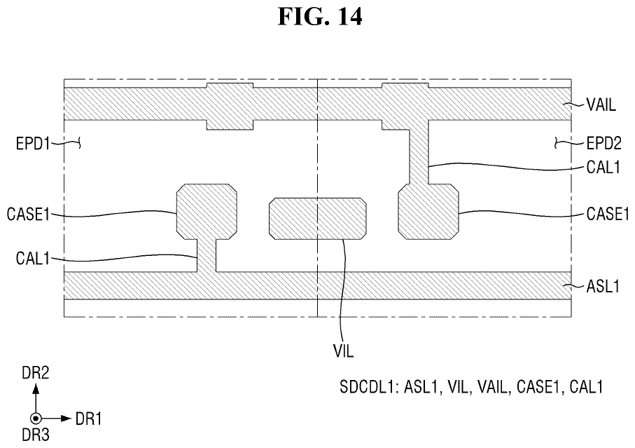

FIGS. 14, 15, 16, 17, and 18 are plan views illustrating a part of each of the first light emitting pixel driver and the second light emitting pixel driver of FIG. 13 according to one or more embodiments.

FIGS. 14, 15, 16, 17, and 18 are drawings illustrating electrical connections between the wires in the first direction DR1 and the wires in the second direction DR2, according to one or more embodiments. Accordingly, in the following description and in FIGS. 14, 15, 16, 17, and 18, the first bypass auxiliary line TASL1 (see FIG. 11) and the power auxiliary horizontal lines VSAHL (see FIG. 11) may be collectively referred to as the first auxiliary line ASL1, and the second bypass auxiliary line TASL2 (see FIG. 11) and the auxiliary vertical lines DCASL (see FIG. 13) may be collectively referred to as the second auxiliary line ASL2. Here, the auxiliary vertical lines DCASL (see FIG. 13) include the first auxiliary vertical line DCASL1 (see FIG. 13), the second auxiliary vertical line DCASL2 (see FIG. 13), and the third auxiliary vertical line DCASL3 (see FIG. 13). In addition, in FIGS. 14, 15, 16, 17, and 18, the power additional line ASL31, the first initialization voltage additional line ASL32, and the second initialization voltage additional line ASL33 may be collectively referred to as the third auxiliary line ASL3.

As shown in FIG. 14, according to one or more embodiments, the circuit layer 120 may include first connection auxiliary electrodes CASE1 having an island shape and spaced (e.g., spaced apart) from the first auxiliary lines ASL1, in each of the light emitting pixel drivers EPD1 and EPD2.

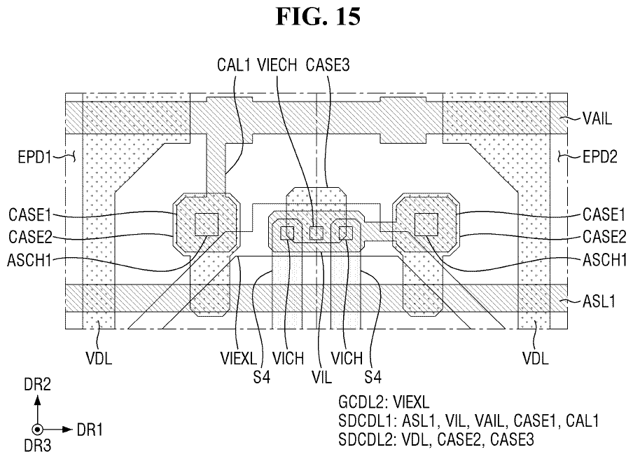

As shown in FIGS. 14 and 15, according to one or more embodiments, the circuit layer 120 may further include the first initialization voltage line VIL having an island shape and located between the first connection auxiliary electrode CASE1 of the first light emitting pixel driver EPD1 and the first connection auxiliary electrode CASE1 of the second light emitting pixel driver EPD2, and the second initialization voltage line VAIL extending in the first direction DR1, spaced (e.g., spaced apart) from the first connection auxiliary electrodes CASE1, and transmitting the second initialization voltage VAINT (see FIG. 8).

The first initialization voltage line VIL may be electrically connected to an initialization voltage extension line VIEXL, which extends in the first direction DR1 and transmits the first initialization voltage VINT (see FIG. 8), through an initialization extension connection hole VIECH. For reference, the first initialization voltage line VIL of FIG. 13 refers collectively to the first initialization voltage line VIL and the initialization voltage extension line VIEXL of FIG. 15.

The first connection auxiliary electrode CASE1 of the first light emitting pixel driver EPD1, the first connection auxiliary electrode CASE1 of the second light emitting pixel driver EPD2, and the first initialization voltage line VIL may be disposed between the second initialization voltage line VAIL and the first auxiliary line ASL1 in the second direction DR2.

In one or more embodiments, the first connection auxiliary electrode CASE1 of the first light emitting pixel driver EPD1 and the first connection auxiliary electrode CASE1 of the second light emitting pixel driver EPD2 may each be electrically connected to one of one first auxiliary line ASL1, the first initialization voltage line VIL, and the second initialization voltage line VAIL through a first connection auxiliary line CAL1.

In one or more embodiments, the first connection auxiliary line CAL1 may extend from the first connection auxiliary electrode CASE1 to one of one first auxiliary line ASL1, the first initialization voltage line VIL, and the second initialization voltage line VAIL.

In one example, as shown in FIG. 14, the first connection auxiliary electrode CASE1 of the first light emitting pixel driver EPD1 may be electrically connected to the first auxiliary line ASL1 through the first connection auxiliary line CAL1, and the first connection auxiliary electrode CASE1 of the second light emitting pixel driver EPD2 may be electrically connected to the second initialization voltage line VAIL through the first connection auxiliary line CAL1.

In another example, as shown in FIG. 15, the first connection auxiliary electrode CASE1 of the first light emitting pixel driver EPD1 may be electrically connected to the second initialization voltage line VAIL through the first connection auxiliary line CAL1, and the first connection auxiliary electrode CASE1 of the second light emitting pixel driver EPD2 may be electrically connected to the first initialization voltage line VIL through the first connection auxiliary line CAL1.

However, the illustrations of FIGS. 14 and 15 are merely examples, and the disposition and shape of the first connection auxiliary line CAL1 in each light emitting pixel driver EPD may be varied.

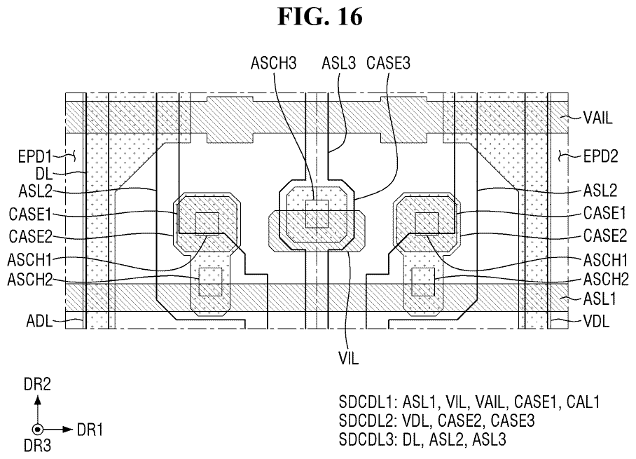

As shown in FIGS. 15 and 16, according to one or more embodiments, the circuit layer 120 may further include second connection auxiliary electrodes CASE2 having an island shape, and respectively overlapping the first connection auxiliary electrodes CASE1.

The second connection auxiliary electrodes CASE2 may be electrically connected to the first connection auxiliary electrodes CASE1 through first auxiliary connection holes ASCH1.

The second connection auxiliary electrodes CASE2 may be electrically connected to the second auxiliary lines ASL2 through second auxiliary connection holes ASCH2.

According to one or more embodiments, the circuit layer 120 may further include third connection auxiliary electrodes CASE3 having an island shape, overlapping the third auxiliary lines ASL3 and spaced (e.g., spaced apart) from the second connection auxiliary electrodes CASE2.

One of the third connection auxiliary electrodes CASE3 may be disposed between the second connection auxiliary electrode CASE2 of the first light emitting pixel driver EPD1 and the second connection auxiliary electrode CASE2 of the second light emitting pixel driver EPD2.

According to one or more embodiments, the first power line VDL for transmitting the first power ELVDD (see FIG. 8) in the circuit layer 120 may be spaced (e.g., spaced apart) from the second connection auxiliary electrodes CASE2 and the third connection auxiliary electrodes CASE3.

The first auxiliary lines ASL1, the first initialization voltage line VIL, the second initialization voltage line VAIL, the first connection auxiliary electrodes CASE1, and the first connection auxiliary line CAL1 may be disposed in a first source-drain conductive layer SDCDL1 on the additional interlayer insulating layer 124 (see FIG. 9).

The second connection auxiliary electrodes CASE2, the third connection auxiliary electrodes CASE3, and the first power line VDL may be disposed in a second source-drain conductive layer SDCDL2 on the first planarization layer 127 (see FIG. 9).

The data lines DL, the second auxiliary lines ASL2, and the third auxiliary lines ASL3 may be disposed in a third source-drain conductive layer SDCDL3 on the second planarization layer 128 (see FIG. 9).

In this case, the first auxiliary connection hole ASCH1 for electrical connection between the first connection auxiliary electrode CASE1 and the second connection auxiliary electrode CASE2 may penetrate the first planarization layer 127 (see FIG. 9). In addition, the second auxiliary connection hole ASCH2 for electrical connection between the second connection auxiliary electrode CASE2 and the second auxiliary line ASL2 may penetrate the second planarization layer 128 (see FIG. 9).

Accordingly, in one of the light emitting pixel drivers EPD, from among the first auxiliary line ASL1, the first initialization voltage line VIL, and the second initialization voltage line VAIL, one wire in the first direction DR1 connected to the first connection auxiliary electrode CASE1 through the first connection auxiliary line CAL1 may be electrically connected to the second auxiliary line ASL2 through the second connection auxiliary electrode CASE2.

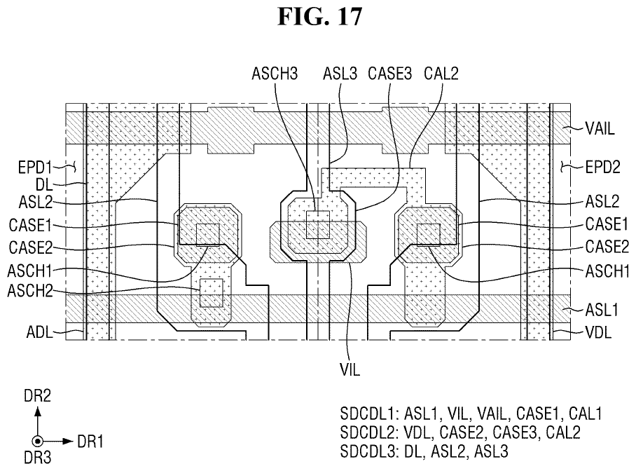

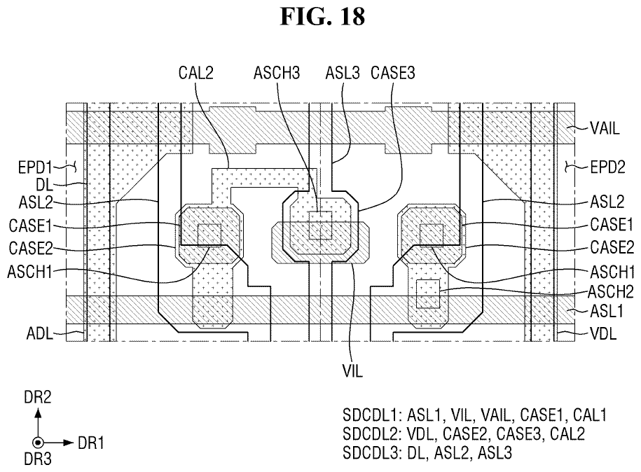

Alternatively, as shown in FIGS. 17 and 18, one of the second connection auxiliary electrode CASE2 of the first light emitting pixel driver EPD1 and the second connection auxiliary electrode CASE2 of the second light emitting pixel driver EPD2 may be electrically connected to the third connection auxiliary electrode CASE3 through a second connection auxiliary line CAL2 without being electrically connected to the second auxiliary line ASL2 through the second auxiliary connection hole ASCH2.

In one example, as shown in FIG. 17, the second connection auxiliary electrode CASE2 of the first light emitting pixel driver EPD1 may be electrically connected to one second auxiliary line ASL2 through the second auxiliary connection hole ASCH2, and the second connection auxiliary electrode CASE2 of the second light emitting pixel driver EPD2 may be electrically connected to the third connection auxiliary electrode CASE3 through the second connection auxiliary line CAL2.

In another example, as shown in FIG. 18, the second connection auxiliary electrode CASE2 of the first light emitting pixel driver EPD1 may be electrically connected to the third connection auxiliary electrode CASE3 through the second connection auxiliary line CAL2, and the second connection auxiliary electrode CASE2 of the second light emitting pixel driver EPD2 may be electrically connected to another second auxiliary line ASL2 through the second auxiliary connection hole ASCH2.

The third connection auxiliary electrode CASE3 may be electrically connected to the third auxiliary line ASL3 through a third auxiliary connection hole ASCH3.

Accordingly, in another one of the light emitting pixel drivers EPD, from among the first auxiliary line ASL1, the first initialization voltage line VIL, and the second initialization voltage line VAIL, one wire in the first direction DR1 connected to the first connection auxiliary electrode CASE1 through the first connection auxiliary line CAL1 may be electrically connected to the third auxiliary line ASL3 through the second connection auxiliary electrode CASE2 and the third connection auxiliary electrode CASE3.

Referring to FIGS. 11, 14, and 16, from among the first auxiliary lines ASL1, the first bypass auxiliary line TASL1 for transmitting the data signal Vdata of the first data line DL1 may be electrically connected to the second bypass auxiliary line TASL2 of the second auxiliary lines ASL2 through the first connection auxiliary electrode CASE1 and the second connection auxiliary electrode CASE2 of a bypass connection light emitting pixel driver that overlaps the crossing between the first bypass auxiliary line TASL1 and the second bypass auxiliary line TASL2 from among the light emitting pixel drivers EPD. That is, the first bypass auxiliary line TASL1 is electrically connected to the first connection auxiliary electrode CASE1 through the first connection auxiliary line CAL1, the first connection auxiliary electrode CASE1 is electrically connected to the second connection auxiliary electrode CASE2 through the first auxiliary connection hole ASCH1, and the second connection auxiliary electrode CASE2 is electrically connected to the second bypass auxiliary line TASL2 of the second auxiliary lines ASL2 through the second auxiliary connection hole ASCH2. Thus, electrical connection between the first bypass auxiliary line TASL1 and the second bypass auxiliary line TASL2 may be implemented in the bypass connection light emitting pixel driver.

Referring to FIGS. 13, 14, and 16, from among the first auxiliary lines ASL1, the power auxiliary horizontal line VSAHL for transmitting the second power ELVSS (see FIG. 8) may be electrically connected to the first auxiliary vertical line DCASL1 of the second auxiliary lines ASL2 through the first connection auxiliary electrode CASE1 and the second connection auxiliary electrode CASE2 of one power connection light emitting pixel driver from among the light emitting pixel drivers EPD. That is, the power auxiliary horizontal line VSAHL is electrically connected to the first connection auxiliary electrode CASE1 through the first connection auxiliary line CAL1, the first connection auxiliary electrode CASE1 is electrically connected to the second connection auxiliary electrode CASE2 through the first auxiliary connection hole ASCH1, and the second connection auxiliary electrode CASE2 is electrically connected to the first auxiliary vertical line DCASL1 of the second auxiliary lines ASL2 through the second auxiliary connection hole ASCH2. Thus, electrical connection between the power auxiliary horizontal line VSAHL and the first auxiliary vertical line DCASL1 may be implemented in one power connection light emitting pixel driver.

Alternatively, referring to FIGS. 13, 15, 17, and 18, from among the first auxiliary lines ASL1, the power auxiliary horizontal line VSAHL for transmitting the second power ELVSS (see FIG. 8) may be electrically connected to the power additional line ASL31 of the third auxiliary lines ASL3 through the first connection auxiliary electrode CASE1, the second connection auxiliary electrode CASE2, and the third connection auxiliary electrode CASE3 of another power connection light emitting pixel driver from among the light emitting pixel drivers EPD. That is, the power auxiliary horizontal line VSAHL is electrically connected to the first connection auxiliary electrode CASE1 through the first connection auxiliary line CAL1, the first connection auxiliary electrode CASE1 is electrically connected to the second connection auxiliary electrode CASE2 through the first auxiliary connection hole ASCH1, the second connection auxiliary electrode CASE2 is electrically connected to the third connection auxiliary electrode CASE3 through the second connection auxiliary line CAL2, and the third connection auxiliary electrode CASE3 is electrically connected to the power additional line ASL31 of the third auxiliary lines ASL3 through the third auxiliary connection hole ASCH3. Thus, electrical connection between the power auxiliary horizontal line VSAHL and the power additional line ASL31 may be implemented in another power connection light emitting pixel driver.

Referring to FIGS. 13, 15, and 16, the first initialization voltage line VIL for transmitting the first initialization voltage VINT (see FIG. 8) may be electrically connected to the second auxiliary vertical line DCASL2 of the second auxiliary lines ASL2 through the first connection auxiliary electrode CASE1 and the second connection auxiliary electrode CASE2 of one first initialization connection light emitting pixel driver from among the light emitting pixel drivers EPD. That is, the first initialization voltage line VIL is electrically connected to the first connection auxiliary electrode CASE1 through the first connection auxiliary line CAL1, the first connection auxiliary electrode CASE1 is electrically connected to the second connection auxiliary electrode CASE2 through the first auxiliary connection hole ASCH1, and the second connection auxiliary electrode CASE2 is electrically connected to the second auxiliary vertical line DCASL2 of the second auxiliary lines ASL2 through the second auxiliary connection hole ASCH2. Thus, electrical connection between the first initialization voltage line VIL and the second auxiliary vertical line DCASL2 may be implemented in one first initialization connection light emitting pixel driver.

Alternatively, referring to FIGS. 13, 15, 17, and 18, the first initialization voltage line VIL for transmitting the first initialization voltage VINT (see FIG. 8) may be electrically connected to the first initialization voltage additional line ASL32 of the third auxiliary lines ASL3 through the first connection auxiliary electrode CASE1, the second connection auxiliary electrode CASE2, and the third connection auxiliary electrode CASE3 of another first initialization connection light emitting pixel driver from among the light emitting pixel drivers EPD. That is, the first initialization voltage line VIL is electrically connected to the first connection auxiliary electrode CASE1 through the first connection auxiliary line CAL1, the first connection auxiliary electrode CASE1 is electrically connected to the second connection auxiliary electrode CASE2 through the first auxiliary connection hole ASCH1, the second connection auxiliary electrode CASE2 is electrically connected to the third connection auxiliary electrode CASE3 through the second connection auxiliary line CAL2, and the third connection auxiliary electrode CASE3 is electrically connected to the first initialization voltage additional line ASL32 of the third auxiliary lines ASL3 through the third auxiliary connection hole ASCH3. Thus, electrical connection between the first initialization voltage line VIL and the first initialization voltage additional line ASL32 may be implemented in another first initialization connection light emitting pixel driver.

Referring to FIGS. 13, 14, 15, and 16, the second initialization voltage line VAIL for transmitting the second initialization voltage VAINT (see FIG. 8) may be electrically connected to the third auxiliary vertical line DCASL3 of the second auxiliary lines ASL2 through the first connection auxiliary electrode CASE1 and the second connection auxiliary electrode CASE2 of one second initialization connection light emitting pixel driver from among the light emitting pixel drivers EPD. That is, the second initialization voltage line VAIL is electrically connected to the first connection auxiliary electrode CASE1 through the first connection auxiliary line CAL1, the first connection auxiliary electrode CASE1 is electrically connected to the second connection auxiliary electrode CASE2 through the first auxiliary connection hole ASCH1, and the second connection auxiliary electrode CASE2 is electrically connected to the third auxiliary vertical line DCASL3 of the second auxiliary lines ASL2 through the second auxiliary connection hole ASCH2. Thus, electrical connection between the second initialization voltage line VAIL and the third auxiliary vertical line DCASL3 may be implemented in one second initialization connection light emitting pixel driver.

Alternatively, referring to FIGS. 13, 14, 15, 17, and 18, the second initialization voltage line VAIL for transmitting the second initialization voltage VAINT (see FIG. 8) may be electrically connected to the second initialization voltage additional line ASL33 of the third auxiliary lines ASL3, through the first connection auxiliary electrode CASE1, the second connection auxiliary electrode CASE2, and the third connection auxiliary electrode CASE3 of another second initialization connection light emitting pixel driver from among the light emitting pixel drivers EPD. That is, the second initialization voltage line VAIL is electrically connected to the first connection auxiliary electrode CASE1 through the first connection auxiliary line CAL1, the first connection auxiliary electrode CASE1 is electrically connected to the second connection auxiliary electrode CASE2 through the first auxiliary connection hole ASCH1, the second connection auxiliary electrode CASE2 is electrically connected to the third connection auxiliary electrode CASE3 through the second connection auxiliary line CAL2, and the third connection auxiliary electrode CASE3 is electrically connected to the second initialization voltage additional line ASL33 of the third auxiliary lines ASL3 through the third auxiliary connection hole ASCH3. Thus, electrical connection between the second initialization voltage line VAIL and the second initialization voltage additional line ASL33 may be implemented in another second initialization connection light emitting pixel driver.

As described above, according to one or more embodiments, by selectively disposing the first connection auxiliary electrode CASE1, the second connection auxiliary electrode CASE2, the first connection auxiliary line CAL1, and the second connection auxiliary line CAL2 provided in each light emitting pixel driver EPD, electrical connection between one of the first auxiliary line ASL1, the first initialization voltage line VIL and the second initialization voltage line VAIL, and one of the second auxiliary line ASL2 and the third auxiliary line ASL3 may be implemented, thereby providing mesh-shaped wires.

Accordingly, the mesh-shaped wires may be provided while reducing the number of connection holes disposed in each light emitting pixel driver EPD. Therefore, the width of each of the light emitting pixel drivers EPD may be reduced, while preventing image quality degradation, which may be desirable for achieving high resolution.

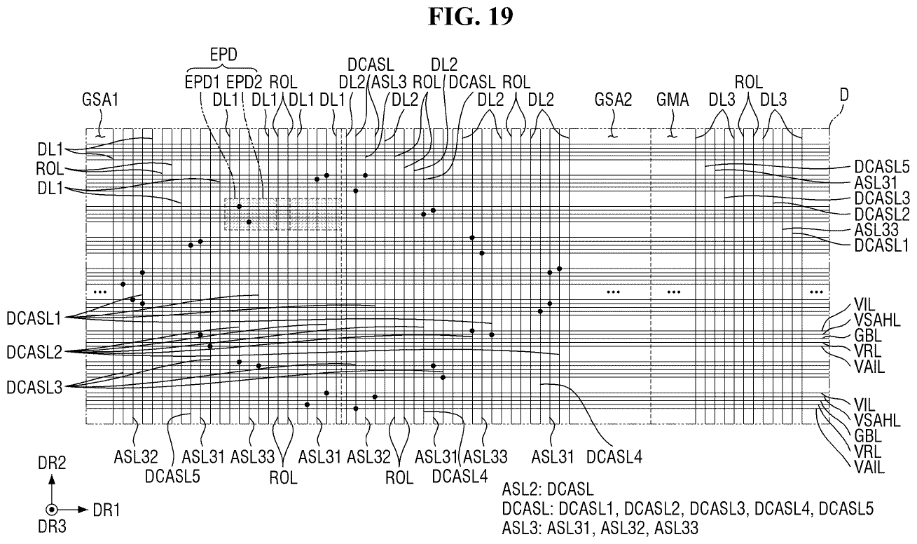

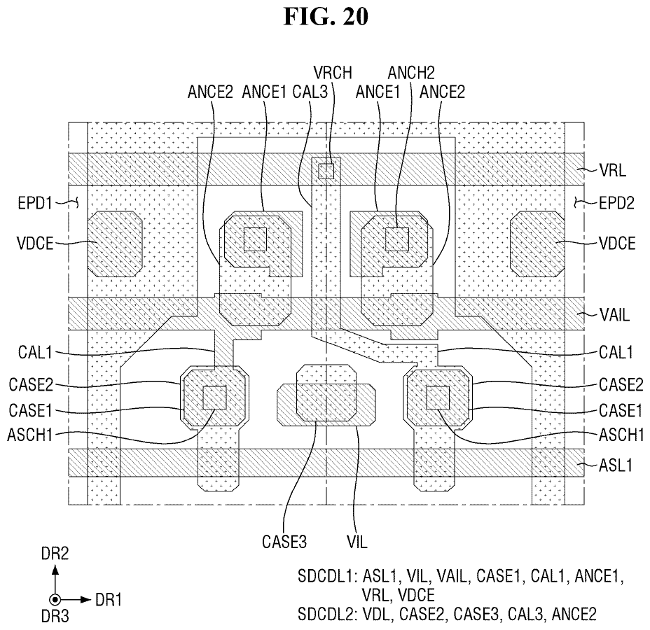

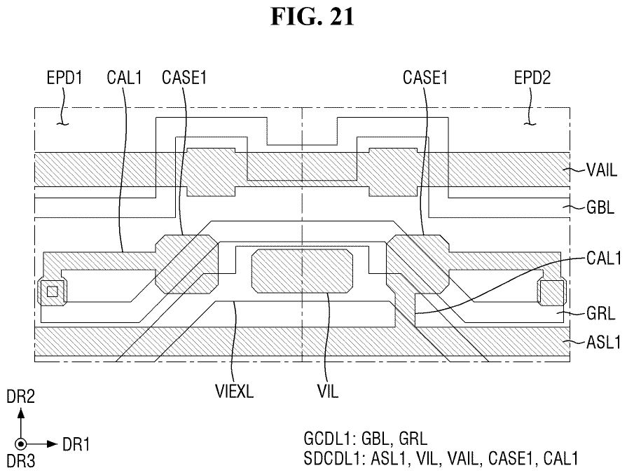

FIG. 19 is a plan view showing a part D of FIG. 10 according to one or more embodiments. FIGS. 20 and 21 are plan views showing a part of each of a first light emitting pixel driver and a second light emitting pixel driver of FIG. 19 according to one or more embodiments.

One embodiment of FIGS. 19, 20, and 21 is substantially the same as the embodiments of FIGS. 13-18, except that the wires in the first direction DR1 further include the reset voltage line VRL and the reset control line GRL in addition to the first auxiliary line ASL1, the first initialization voltage line VIL, and the second initialization voltage line VAIL, and therefore, redundant description will be omitted below.

As shown in FIG. 19, according to one or more embodiments, the auxiliary vertical lines DCASL of the second auxiliary lines ASL2 may further include a fourth auxiliary vertical line for transmitting the reset voltage VRST (see FIG. 8), and a fifth auxiliary vertical line DCASL5 for transmitting the reset control signal GR (see FIG. 8) in addition to the first auxiliary vertical line DCASL1 for transmitting the second power ELVSS (see FIG. 8), the second auxiliary vertical line DCASL2 for transmitting the first initialization voltage VINT (see FIG. 8), and the third auxiliary vertical line DCASL3 for transmitting the second initialization voltage VAINT (see FIG. 8).

As shown in FIG. 20, according to one or more embodiments, the circuit layer 120 may further include a first power connection electrode VDCE disposed in each light emitting pixel driver EPD, the first anode connection electrode ANCE1, the second anode connection electrode ANCE2, and the reset voltage line VRL extending in the first direction DR1 and transmitting the reset voltage VRST (see FIG. 8).

The first power connection electrode VDCE may be electrically connected to the first power line VDL.

The second anode connection electrode ANCE2 may be electrically connected to the first anode connection electrode ANCE1 through a second anode connection hole ANCH2.

The reset voltage line VRL, the first power connection electrode VDCE, and the first anode connection electrode ANCE1 may be disposed in the first source-drain conductive layer SDCDL1 on the interlayer insulating layer 126 (see FIG. 9).

In one example, the first power connection electrode VDCE and the first anode connection electrode ANCE1 may be spaced (e.g., spaced apart) from each other and disposed between the reset voltage line VRL and the second initialization voltage line VAIL in the second direction DR2.

According to one or more embodiments, the reset voltage line VRL may be electrically connected to the second connection auxiliary electrode CASE2 of one of the light emitting pixel drivers EPD through a third connection auxiliary line CAL3.

Because the second initialization voltage line VAIL is disposed between the reset voltage line VRL and the first and second connection auxiliary electrodes CASE1 and CASE2, the third connection auxiliary line CAL3 crosses the second initialization voltage line VAIL. Accordingly, the third connection auxiliary line CAL3 may be disposed in a different conductive layer than the second initialization voltage line VAIL.

In one example, the third connection auxiliary line CAL3 may be disposed in the second source-drain conductive layer SDCDL2 on the first planarization layer 127 (see FIG. 9).

The third connection auxiliary line CAL3 may be electrically connected to the reset voltage line VRL through a reset voltage connection hole VRCH, and may extend to the second connection auxiliary electrode CASE2.

Referring to FIGS. 16 and 20, the reset voltage line VRL for transmitting the reset voltage VRST (see FIG. 8) may be electrically connected to the fourth auxiliary vertical line of the second auxiliary lines ASL2 through the second connection auxiliary electrode CASE2 of one reset voltage connection light emitting pixel driver from among the light emitting pixel drivers EPD. That is, the reset voltage line VRL may be electrically connected to the second connection auxiliary electrode CASE2 through the third connection auxiliary line CAL3, and the second connection auxiliary electrode CASE2 may be electrically connected to the fourth auxiliary vertical line of the second auxiliary lines ASL2 through the second auxiliary connection hole ASCH2. Thus, electrical connection between the reset voltage line VRL and the fourth auxiliary vertical line may be implemented in one reset voltage connection light emitting pixel driver.

As shown in FIG. 21, according to one or more embodiments, the circuit layer 120 may further include the reset control line GRL extending in the first direction DR1 and transmitting the reset control signal GR (see FIG. 8).

The reset of the element output node NOP by the reset voltage VRST may be uniformly performed in all light sensing pixel drivers DPD. That is, the reset control signal GR may be transmitted concurrently (e.g., simultaneously) to the light sensing pixel drivers DPD of the display area DA.

According to one or more embodiments, in order to prevent delays caused by resistance in the reset control line GRL, the reset control signal GR (see FIG. 8) may be supplied to the light sensing pixel drivers DPD through mesh-shaped wires including the reset control line GRL and the fifth auxiliary vertical line DCASL5.

Referring to FIGS. 16 and 21, the reset control line GRL for transmitting the reset control signal GR (see FIG. 8) may be electrically connected to the fifth auxiliary vertical line DCASL5 of the second auxiliary lines ASL2 through the first connection auxiliary electrode CASE1 and the second connection auxiliary electrode CASE2 of one reset control connection light emitting pixel driver among the light emitting pixel drivers EPD. That is, the reset control line GRL may be electrically connected to the first connection auxiliary line CAL1 through a connection hole, the first connection auxiliary line CAL1 may be electrically connected to the first connection auxiliary electrode CASE1, the first connection auxiliary electrode CASE1 may be electrically connected to the second connection auxiliary electrode CASE2 through the first auxiliary connection hole ASCH1, and the second connection auxiliary electrode CASE2 may be electrically connected to the fifth auxiliary vertical line DCASL5 of the second auxiliary lines ASL2 through the second auxiliary connection hole ASCH2. Thus, electrical connection between the reset control line GRL and the fifth auxiliary vertical line DCASL5 may be implemented in one reset control connection light emitting pixel driver.

As described above, according to one or more embodiments, the reset voltage VRST (see FIG. 8) and the reset control signal GR (see FIG. 8) may be supplied through mesh-shaped wires by selectively disposing the first connection auxiliary electrode CASE1, the second connection auxiliary electrode CASE2, the first connection auxiliary line CAL1, and the third connection auxiliary line CAL3 provided in each of the light emitting pixel drivers EPD. Accordingly, the reset voltage VRST (see FIG. 8) and the reset control signal GR (see FIG. 8) may be supplied through mesh-shaped wires without increasing the number of connection holes arranged in each light emitting pixel driver EPD, thereby improving the accuracy of light sensing, which is desirable for achieving high resolution.

However, the effects, aspects, and features of the present disclosure are not restricted to the one set forth herein. The above and other effects, aspects, and features of the present disclosure will become more apparent to one of daily skill in the art to which the present disclosure pertains by referencing the claims.

What is claimed is:

1. A display device comprising:
a substrate comprising a display area in which emission areas are arranged and a non-display area around the display area;
a circuit layer on the substrate; and
an element layer on the circuit layer, and comprising light emitting elements respectively located in the emission areas,
wherein the circuit layer comprises:
light emitting pixel drivers electrically connected to the light emitting elements, and arranged side by side with each other along a first direction and a second direction;
data lines extending in the second direction, and transmitting a data signal to the light emitting pixel drivers;
first auxiliary lines extending in the first direction;
second auxiliary lines extending in the second direction and adjacent to the data lines in the first direction;
third auxiliary lines extending in the second direction, and located between the second auxiliary lines in the first direction; and
first connection auxiliary electrodes respectively located in the light emitting pixel drivers, having an island shape, and spaced from the first auxiliary lines.

2. The display device of claim 1, wherein the circuit layer further comprises second connection auxiliary electrodes having an island shape and respectively overlapping the first connection auxiliary electrodes, and respectively electrically connected to the first connection auxiliary electrodes through first auxiliary connection holes, and
wherein the second connection auxiliary electrodes are electrically connected to the second auxiliary lines through second auxiliary connection holes.

3. The display device of claim 2, wherein the circuit layer further comprises:
a first initialization voltage line electrically connected to an initialization voltage extension line transmitting a first initialization voltage and extending in the first direction, having an island shape, and spaced from the first connection auxiliary electrodes;
a second initialization voltage line extending in the first direction, spaced from the first connection auxiliary electrodes, and transmitting a second initialization voltage; and
third connection auxiliary electrodes overlapping the third auxiliary lines and having an island shape, and spaced from the second connection auxiliary electrodes,
wherein the third connection auxiliary electrodes are electrically connected to the third auxiliary lines through third auxiliary connection holes.

4. The display device of claim 3, wherein the light emitting pixel drivers comprise a first light emitting pixel driver and a second light emitting pixel driver that are adjacent to each other in the first direction,
wherein one of the first auxiliary lines overlaps the first light emitting pixel driver and the second light emitting pixel driver,
wherein the second auxiliary lines comprise a second auxiliary line overlapping the first light emitting pixel driver, and another second auxiliary line overlapping the second light emitting pixel driver,
wherein the third auxiliary lines comprise a third auxiliary line adjacent to a boundary between the first light emitting pixel driver and the second light emitting pixel driver, and
the first initialization voltage line is located between the first connection auxiliary electrode of the first light emitting pixel driver and the first connection auxiliary electrode of the second light emitting pixel driver in the first direction, and overlaps the third auxiliary line.

5. The display device of claim 4, wherein each of the first connection auxiliary electrode of the first light emitting pixel driver and the first connection auxiliary electrode of the second light emitting pixel driver is electrically connected to one of the first auxiliary lines, the first initialization voltage line, or the second initialization voltage line through a first connection auxiliary line.

6. The display device of claim 4, wherein the third connection auxiliary electrodes comprise a third connection auxiliary electrode electrically connected to the third auxiliary line, and
one of the second connection auxiliary electrode of the first light emitting pixel driver or the second connection auxiliary electrode of the second light emitting pixel driver is electrically connected, through a second connection auxiliary line, to a third connection auxiliary electrode between the second connection auxiliary electrode of the first light emitting pixel driver and the second connection auxiliary electrode of the second light emitting pixel driver from among the third connection auxiliary electrodes.

7. The display device of claim 3, wherein a bypass area on one side of the display area comprises:
a bypass middle area;
a first bypass side area parallel to the bypass middle area in the first direction and in contact with the non-display area in the first direction; and
a second bypass side area located between the bypass middle area and the first bypass side area,
the data lines comprising a first data line in the first bypass side area, and a second data line in the second bypass side area,
the first auxiliary lines comprising:
a first bypass auxiliary line electrically connected to the first data line; and
power auxiliary horizontal lines configured to transmit, between a first power and a second power for driving the light emitting elements, the second power,
the second auxiliary lines comprising a second bypass auxiliary line adjacent to the second data line and electrically connected to the first bypass auxiliary line, and
auxiliary vertical lines, the auxiliary vertical lines being a remainder of the second auxiliary lines excluding the second bypass auxiliary line and comprising:
a first auxiliary vertical line configured to transmit the second power;
a second auxiliary vertical line configured to transmit the first initialization voltage; and
a third auxiliary vertical line configured to transmit the second initialization voltage.

8. The display device of claim 7, wherein the first bypass auxiliary line from among the first auxiliary lines is electrically connected to the first connection auxiliary electrode of one of the light emitting pixel drivers through a first connection auxiliary line, and
the second connection auxiliary electrode of the one light emitting pixel driver is electrically connected to the second bypass auxiliary line from among the second auxiliary lines through a second auxiliary connection hole.

9. The display device of claim 7, wherein from among the first auxiliary lines, the power auxiliary horizontal line is electrically connected to the first connection auxiliary electrode of one of the light emitting pixel drivers through a first connection auxiliary line, and
wherein the second connection auxiliary electrode of the one light emitting pixel driver is electrically connected to the first auxiliary vertical line from among the second auxiliary lines through a second auxiliary connection hole.

10. The display device of claim 7, wherein the first initialization voltage line is electrically connected to the first connection auxiliary electrode of one of the light emitting pixel drivers through a first connection auxiliary line, and
wherein the second connection auxiliary electrode of the one light emitting pixel driver is electrically connected to the second auxiliary vertical line from among the second auxiliary lines through a second auxiliary connection hole.

11. The display device of claim 7, wherein the second initialization voltage line is electrically connected to the first connection auxiliary electrode of one of the light emitting pixel drivers through a first connection auxiliary line, and
the second connection auxiliary electrode of the one light emitting pixel driver is electrically connected to the third auxiliary vertical line from among the second auxiliary lines through a second auxiliary connection hole.

12. The display device of claim 7, wherein the circuit layer further comprises third connection auxiliary electrodes overlapping the third auxiliary lines and spaced from the second connection auxiliary electrodes, and
the third auxiliary lines comprise:
a power additional line configured to transmit the second power;
a first initialization voltage additional line configured to transmit the first initialization voltage; and
a second initialization voltage additional line configured to transmit the second initialization voltage.

13. The display device of claim 12, wherein from among the first auxiliary lines, the power auxiliary horizontal line is electrically connected to the first connection auxiliary electrode of one of the light emitting pixel drivers through a first connection auxiliary line,
wherein the second connection auxiliary electrode of the light emitting pixel driver is electrically connected to one of the third connection auxiliary electrodes overlapping the power additional line from among the third connection auxiliary electrodes through a second connection auxiliary line, and
wherein the one third connection auxiliary electrode is electrically connected to the power additional line through a third auxiliary connection hole.

14. The display device of claim 12, wherein the first initialization voltage line is electrically connected to the first connection auxiliary electrode of one of the light emitting pixel drivers through a first connection auxiliary line,
wherein the second connection auxiliary electrode of the light emitting pixel driver is electrically connected to one of the third connection auxiliary electrodes overlapping the first initialization voltage additional line from among the third connection auxiliary electrodes through a second connection auxiliary line, and
wherein the third connection auxiliary electrode is electrically connected to the first initialization voltage additional line through a third auxiliary connection hole.

15. The display device of claim 12, wherein the second initialization voltage line is electrically connected to the first connection auxiliary electrode of one of the light emitting pixel drivers through a first connection auxiliary line,
wherein the second connection auxiliary electrode of the one light emitting pixel driver is electrically connected to one of the third connection auxiliary electrodes overlapping the second initialization voltage additional line from among the third connection auxiliary electrodes through a second connection auxiliary line, and
wherein the one third connection auxiliary electrode is electrically connected to the second initialization voltage additional line through a third auxiliary connection hole.

16. The display device of claim 7, wherein the display area comprises a non-emission area which is a separation region between the emission areas; and light sensing areas in parts of the non-emission area,
wherein the element layer further comprises light sensing elements respectively located in the light sensing areas,
wherein the circuit layer further comprises:
light sensing pixel drivers electrically connected to the light sensing elements;
a reset control line extending in the first direction, and configured to transmit a reset control signal for resetting the light sensing pixel drivers; and
a reset voltage line configured to transmit a reset voltage to the light sensing pixel drivers,
wherein the auxiliary vertical lines of the second auxiliary lines further comprise at least one of a fourth auxiliary vertical line configured to transmit the reset voltage, or a fifth auxiliary vertical line configured to transmit the reset control signal.

17. The display device of claim 16, wherein the reset voltage line is electrically connected to the second connection auxiliary electrode of one of the light emitting pixel drivers through a third connection auxiliary line, and
wherein the second connection auxiliary electrode of the one of the light emitting pixel drivers is electrically connected to the fourth auxiliary vertical line from among the second auxiliary lines through a second auxiliary connection hole.

18. The display device of claim 16, wherein the reset control line is electrically connected to the first connection auxiliary electrode of one of the light emitting pixel drivers through a reset control connection hole and a first connection auxiliary line, and
wherein the second connection auxiliary electrode of the one light emitting pixel driver is electrically connected to the fifth auxiliary vertical line from among the second auxiliary lines through a second auxiliary connection hole.

19. The display device of claim 3, wherein the circuit layer further comprises:
a first semiconductor layer on the substrate;
a first gate insulating layer covering the first semiconductor layer;
a first gate conductive layer on the first gate insulating layer;
a second gate insulating layer covering the first gate conductive layer;
a second gate conductive layer on the second gate insulating layer;
an additional interlayer insulating layer covering the second gate conductive layer;
a second semiconductor layer on the additional interlayer insulating layer;
a third gate insulating layer covering the second semiconductor layer;
a third gate conductive layer on the third gate insulating layer;
an interlayer insulating layer covering the third gate conductive layer;
a first source-drain conductive layer on the interlayer insulating layer;
a first planarization layer covering the first source-drain conductive layer;
a second source-drain conductive layer on the first planarization layer;
a second planarization layer covering the second source-drain conductive layer;
a third source-drain conductive layer on the second planarization layer; and
a third planarization layer covering the third source-drain conductive layer,
wherein the first auxiliary lines, the first connection auxiliary electrodes, the first initialization voltage line, and the second initialization voltage line are on the first source-drain conductive layer,
wherein the second connection auxiliary electrodes and the third connection auxiliary electrodes are in the second source-drain conductive layer, and
wherein the second auxiliary lines and the third auxiliary lines are in the third source-drain conductive layer.

20. A display device comprising:
a substrate including a display area in which emission areas are arranged and a non-display area around the display area;
a circuit layer on the substrate; and
an element layer on the circuit layer, and comprising light emitting elements respectively located in the emission areas,
wherein the circuit layer comprises:
light emitting pixel drivers electrically connected to the light emitting elements, and arranged side by side with each other in a first direction and a second direction;
data lines extending in the second direction, and configured to transmit a data signal to the light emitting pixel drivers;
first auxiliary lines extending in the first direction;
second auxiliary lines extending in the second direction and adjacent to the data lines in the first direction;
third auxiliary lines extending in the second direction, and located between the second auxiliary lines in the first direction;
first connection auxiliary electrodes respectively located in the light emitting pixel drivers, having an island shape, and spaced from the first auxiliary lines;
second connection auxiliary electrodes, having an island shape, and respectively overlapping the first connection auxiliary electrodes, respectively electrically connected to the first connection auxiliary electrodes through first auxiliary connection holes, and electrically connected to the second auxiliary lines through second auxiliary connection holes;
third connection auxiliary electrodes overlapping the third auxiliary lines, having an island shape, and spaced from the second connection auxiliary electrodes, and electrically connected to the third auxiliary lines through third auxiliary connection holes;
a first initialization voltage line electrically connected to an initialization voltage extension line configured to transmit a first initialization voltage and extending in the first direction, having an island shape, and spaced from the first connection auxiliary electrodes; and
a second initialization voltage line extending in the first direction, spaced from the first connection auxiliary electrodes, and configured to transmit a second initialization voltage,
wherein the first auxiliary lines comprise:
a first bypass auxiliary line electrically connected to a first data line adjacent to the non-display area in the first direction from among the data lines; and
power auxiliary horizontal lines configured to transmit, between a first power and a second power for driving the light emitting elements, the second power, and
wherein the second auxiliary lines comprise:
a second bypass auxiliary line electrically connected to the first bypass auxiliary line and adjacent to a second data line spaced from the non-display area than the first data line in the first direction from among the data lines; and
auxiliary vertical lines, the auxiliary vertical lines being a remainder excluding the second bypass auxiliary line,
wherein the second bypass auxiliary line is electrically connected to the first bypass auxiliary line through a first connection auxiliary electrode, a first connection auxiliary line, and a second connection auxiliary electrode in a bypass connection light emitting pixel driver overlapping a crossing of the first bypass auxiliary line and the second bypass auxiliary line from among the light emitting pixel drivers, and
wherein the auxiliary vertical lines comprise:
a first auxiliary vertical line electrically connected to the power auxiliary horizontal lines through a first connection auxiliary electrode, a first connection auxiliary line, and a second connection auxiliary electrode located in a power connection light emitting pixel driver from among the light emitting pixel drivers;
a second auxiliary vertical line, configured to transmit the first initialization voltage, electrically connected to the first initialization voltage line through a first connection auxiliary electrode, a first connection auxiliary line, and a second connection auxiliary electrode in a first initialization connection light emitting pixel driver from among the light emitting pixel drivers; and
a third auxiliary vertical line electrically connected to the second initialization voltage line through a first connection auxiliary electrode, a first connection auxiliary line, and a second connection auxiliary electrode in a second initialization connection light emitting pixel driver from among the light emitting pixel drivers.
